(19) United States
(12) Patent Application Publication
(10) Pub. No.: US 2004/0238024 A1
(43) Pub. Date: Dec. 2, 2004

(54) Sheet manufacturing device, sheet manufacturing method, and solar battery

(76) Inventors: Shuji Goma, Nara (JP); Hirozumi Gokaku, Nara (JP); Kohzaburon Yano, Mie (JP); Zenpei Tani, Osaka (JP)

Correspondence Address: NIXON & VANDERHYE, PC, 1100 N GLEBE ROAD, 8TH FLOOR, ARLINGTON, VA, 22201-4714, US

(21) Appl. No.: 10/486,221

(22) PCT Filed: Aug. 2, 2002
(86) PCT No.: PCT/JP02/07932

(30) Foreign Application Priority Data
Aug. 9, 2001 (JP) 2001-242202
Dec. 17, 2001 (JP) 2001-383310

(51) Int. Cl. H02N 6/00; H01L 25/00

(52) U.S. Cl. 136/243; 136/256

(57) ABSTRACT

The present invention is directed to a thin plate manufacturing apparatus for forming a thin plate on the surface of a substrate by dipping the substrate held by a substrate transport mechanism (1) in melting fluid, a thin plate manufacturing method, and a solar cell using the thin plate, the substrate transfer mechanism (1) installed so as to be movable in horizontal direction (104) along a horizontal moving shaft (8) installed so as to be movable along vertical moving shaft (9). Further, the substrate transfer mechanism (1) comprising a means for diagonally inclining the substrate (2) or a means for attaching/detaching the substrate, whereby the thin plate of flat shape can be provided and the shape of the thin plate thus obtained can be optimized.

### TECHNICAL FIELD

The present invention relates to a thin plate manufacturing apparatus and a thin plate manufacturing method, and more specifically, it relates to a thin plate manufacturing apparatus and a thin plate manufacturing method dipping a substrate into a melt thereby growing a thin plate on the substrate and a solar cell.

### BACKGROUND ART

For example, “Manufacturing Apparatus for Silicon Ribbon and Manufacturing Method Thereof” disclosed in Japanese Patent Laying-Open No. 10-29895 can be listed as one of conventional thin plate manufacturing apparatuses. This silicon ribbon manufacturing apparatus employs a structure capable of continuously taking out a silicon thin plate solidified/grown following a carbon net by partially dipping a cylindrical surface of a rotator into a vertically movable crucible and drawing the carbon net while rotating a cooling body. According to this method, it is possible to reduce both of the process cost and the raw material cost as compared with a conventional silicon wafer manufacturing method of obtaining a wafer by slicing an ingot with a wire saw or the like.

The rotated cooling body draws silicon while forcibly cooling the same, whereby the drawing speed can be remarkably improved. Further, it is possible to control the drawing speed in response to the size or the rotational frequency of the rotator, for enabling drawing at a speed of at least 100 mm/min. in general. According to this “Manufacturing Apparatus for Silicon Ribbon and Manufacturing Method Thereof”, however, the thin plate is bent with a curvature remaining in the shape thereof due to the cylindrical rotator.

### DISCLOSURE OF THE INVENTION

An object of the present invention is to provide a thin plate manufacturing apparatus and a thin plate manufacturing method capable of obtaining a flat thin plate and further optimizing the shape of the obtained thin plate and a solar cell.

In order to solve the aforementioned problem, the inventors have deeply made research and development, to find out that the correlation between a substrate (and a thin plate grown on the substrate) and a melt influences the quality of the thin plate and the shape of the thin plate. For example, a large pool remains on an end of the substrate escaping from the melt due to the tension of the melt, unless the substrate is pulled up at an almost perpendicular angle.

When it is intended to control motion of the substrate for improving such correlation between the substrate and the melt and attaining optimum correlation, the control is impossible since the motion cannot be arbitrarily set if the substrate performs rotational motion of moving on a constant trajectory as disclosed in the aforementioned background technique. In order to arbitrarily set the motion of the substrate, therefore, a mechanism for freely operating and transporting the substrate must be designed. In an apparatus according to the present invention, however, a heating mechanism or the like for holding a high-temperature melt may be present and hence a mechanism for transporting a substrate is exposed to a high temperature. Therefore, it is difficult to introduce a complicated substrate transport mechanism, and a substrate transport mechanism reliably executing the minimum necessary operations must be invented.

Accordingly, a thin plate manufacturing apparatus according to an aspect of the present invention is a thin plate manufacturing apparatus for dipping a substrate held by a substrate transport mechanism into a melt thereby forming a thin plate on the surface of the aforementioned substrate, and the aforementioned substrate transport mechanism includes first substrate transport means for transporting the aforementioned substrate in a direction for dipping and taking out the aforementioned substrate into and from the aforementioned melt and second substrate transport means enabling transport of the aforementioned substrate in a second direction different from the aforementioned first direction. This structure is so employed that it is possible to move the substrate at least in two directions when transporting the substrate.

Preferably in the aforementioned invention, the thin plate manufacturing apparatus is rendered capable of independently controlling the aforementioned first substrate transport means and the aforementioned second substrate transport means respectively so that it is possible to separately set a horizontal traveling speed and a vertical traveling speed of the substrate by enabling the first substrate transport means to vertically transport the substrate and enabling the second substrate transport means to horizontally transport the substrate. In other words, it is possible to freely set the trajectory of the substrate in a plane including two directions defined by the first substrate transport means and the second substrate transport means. Thus, the correlation between the substrate (and the thin plate grown on the substrate) and the melt is so optimized that it is possible to attain improvement of the quality of the thin plate, improvement of the shape of the thin plate and improvement of mass productivity of the thin plate.

Preferably in the aforementioned invention, the aforementioned substrate transport mechanism further includes substrate inclination means for inclining the surface of the aforementioned substrate with respect to the level of the aforementioned melt. Further, the aforementioned substrate inclination means is preferably independently controllable with respect to the aforementioned first substrate transport means and the aforementioned second substrate transport means. Thus, the correlation (angle) between the surface of the substrate and the surface of the melt can be so controlled that it is possible to optimize the inclination of the substrate with respect to the surface of the melt when the substrate escapes from the melt.

Preferably in the aforementioned invention, the aforementioned substrate transport mechanism further includes substrate attaching/detaching means for rendering the aforementioned substrate attachable/detachable to/from the aforementioned substrate transport mechanism. Preferably, the aforementioned substrate attaching/detaching means is independently controllable with respect to the aforementioned first substrate transport means, the aforementioned second substrate transport means and the aforementioned substrate inclination means.

This structure is so employed that it is possible to continuously use the substrate transport mechanism by exchanging only the substrate, there is no need to exchange the overall substrate transport mechanism and it is possible to prevent rise of the labor, the time and the cost when the durability of the substrate is limited.

Further, it is possible to attach/detach the aforementioned substrate to/from the aforementioned substrate transport mechanism on a position other than that above melt holding means, so that it is possible to avoid a bad thermal influence such as thermal rupture of the aforementioned substrate attaching/detaching mechanism or a possibility of precision loss resulting from thermal expansion.

If a constant substrate operation trajectory may be regularly implemented as in the case of few quantity producing the thin plate when employing the structure of the aforementioned invention, the object can be satisfied by deciding the optimum trajectory for the thin plate to be obtained and regularly repeating an identical two-directional movement pattern and an identical inclination pattern.

When considering mass production of continuously producing the thin plate or the like, however, a long run is necessary. In this case, it is possible to readily set the movement pattern and the inclination pattern of the substrate to the optimum patterns with time against such factors that the quantity of the melt (the absolute position of the height of the melt or the like) changes with time and the in-apparatus atmosphere changes with time by independently controlling the two directions of movement as described above so that currently suitable movement patterns can be set while enabling the apparatus to also independently control inclination of the surface of the substrate and further enabling the apparatus to control attachment/detachment of the substrate independently of movement and inclination of the substrate in response to time change of the substrate.

Preferably in the aforementioned invention, the thin plate manufacturing apparatus comprises melt holding means holding the aforementioned melt, and further comprises thermal shield means between the aforementioned melt holding means and the aforementioned substrate transport mechanism. Thus, it is possible to suppress heat transfer from the melt holding means to the substrate transport mechanism.

Preferably in the aforementioned invention, the aforementioned substrate transport mechanism includes dip control means dipping the aforementioned substrate into the aforementioned melt of a material containing at least either a metallic material or a semiconductor material and thin plate growth control means taking out the dipped aforementioned substrate from the aforementioned melt thereby growing the thin plate of the aforementioned material on the surface of the aforementioned substrate. Preferably, the said dip control means independently controls the said first substrate transport means and the said second substrate transport means respectively after the said substrate is dipped into the said melt and before the substrate is taken out from the said melt for growing the thin plate on the surface of the said substrate.

Thus, it is possible to separately set a horizontal traveling speed and a vertical traveling speed of the substrate by enabling the first substrate transport means to vertically transport the substrate and enabling the second substrate transport means to horizontally transport the substrate. In other words, it is possible to freely set the trajectory of the substrate in a plane including two directions defined by the first substrate transport means and the second substrate transport means. Thus, the correlation between the substrate (and the thin plate grown on the substrate) and the melt is so optimized that it is possible to attain improvement of the quality of the thin plate, improvement of the shape of the thin plate and improvement of mass productivity of the thin plate.

The substrate may be linearly moved up to immediately before the same is dipped into the melt. In this case, the transit time may conceivably be so reduced that the tact time and the cost can be reduced. Similarly, the two directions may not be independently controlled also after the substrate escapes from the melt, but it is preferable to independently control the substrate in the two directions in the interval between the point when the substrate starts dipping into the melt and the point when the same is taken out from the melt.

Preferably in the aforementioned invention, the aforementioned dip control means controls the aforementioned substrate inclination means independently of the aforementioned first substrate transport means and the aforementioned second substrate transport means after the aforementioned substrate is dipped into the aforementioned melt and before the substrate is taken out from the aforementioned melt.

More specifically, the substrate must be independently controlled and inclined at least after the substrate dips into the melt and before the same separates from the melt. For example, the angle of the substrate may be fixed up to immediately before the substrate dips into the melt. In this case, stability of substrate movement may conceivably be rather improved. Similarly, inclination of the substrate may not be independently controlled also after the substrate escapes from the melt. Therefore, inclination of the substrate must be independently controlled from the point when the substrate starts dipping into the melt up to the point when takeout from the melt is completed.

Thus, it is possible to control the correlation (angle) between the surface of the substrate and the surface of the melt, so that it is possible to optimize the inclination of the substrate with respect to the surface of the melt when the substrate is taken out from the melt.

Preferably in the aforementioned invention, the aforementioned substrate attaching/detaching means includes steps of attaching the aforementioned substrate to the aforementioned substrate transport mechanism before dipping the aforementioned substrate and detaching the aforementioned substrate having the thin plate grown on its surface from the aforementioned substrate transport mechanism after dipping the aforementioned substrate.

Thus, it is possible to carry out a step of detaching the thin plate from the substrate outside the apparatus and to refresh the surface of the substrate every time by attaching the substrate before dipping, detaching the substrate along with the thin plate after dipping and delivering the same from the system, thereby attaining mass productivity of the thin plate.

Preferably in the aforementioned invention, the thin plate manufacturing apparatus comprises a step of detaching the thin plate grown on the surface of the aforementioned substrate from the aforementioned substrate while keeping the aforementioned substrate attached to the aforementioned substrate transport mechanism after dipping the aforementioned substrate. Thus, mass productivity of the thin plate can be attained.

Preferably in the aforementioned invention, the aforementioned melt is a material including silicon.

A thin plate manufacturing method based on the present invention is a thin plate manufacturing method holding a substrate with a substrate transport mechanism and dipping the aforementioned substrate into a melt thereby forming a thin plate on the surface of the aforementioned substrate, and comprises a step of independently controlling first substrate transport means for transporting the aforementioned substrate in a direction for dipping and taking out the aforementioned substrate into and from the aforementioned melt and second substrate transport means enabling transport of the aforementioned substrate in a second direction different from the aforementioned first direction after the aforementioned substrate is dipped into the aforementioned melt and before the substrate is taken out from the aforementioned melt. This step is so employed that it is possible to move the substrate in at least two directions when transporting the substrate.

Preferably in the aforementioned invention, the aforementioned first substrate transport step includes a step of taking out the aforementioned substrate from the aforementioned melt while inclining the aforementioned substrate and pressing the surface of the aforementioned melt with the aforementioned substrate. This step is so employed that the melt regularly progresses in a direction for colliding against the surface of the substrate when the substrate is taken out. Consequently, the melt regularly applies pressure to the substrate, whereby the melt hardly remains on the surface of the substrate and the number of projections formed on the thin plate can be reduced.

Preferably in the aforementioned invention, the thin plate manufacturing method comprises steps of attaching the aforementioned substrate to the aforementioned substrate transport mechanism before dipping the aforementioned substrate and detaching the aforementioned substrate having the thin plate grown on its surface from the aforementioned substrate transport mechanism after dipping the aforementioned substrate. This step is so employed that it is possible to carry out a step of detaching the thin plate from the substrate outside the apparatus and to refresh the surface of the substrate every time by attaching the substrate before dipping, detaching the substrate along with the thin plate after dipping and delivering the same from the system, thereby attaining mass productivity of the thin plate.

Preferably in the aforementioned invention, the thin plate manufacturing method comprises a step of detaching the thin plate grown on the surface of the aforementioned substrate from the aforementioned substrate while keeping the aforementioned substrate attached to the aforementioned substrate transport mechanism after dipping the aforementioned substrate. This step is so employed that mass productivity of the thin plate can be attained.

Preferably in the aforementioned invention, the aforementioned melt is a material including silicon.

A solar cell based on the present invention is prepared with a thin plate manufactured by the aforementioned thin plate manufacturing apparatus or the aforementioned thin plate manufacturing method. In the solar cell prepared with the thin plate manufactured by the aforementioned thin plate manufacturing apparatus or the aforementioned thin plate manufacturing method, it is possible to attain improvement of the yield in manufacturing steps (improvement of the efficiency percentage) and improvement of the solar cell conversion efficiency.

A thin plate manufacturing apparatus according to another aspect of the present invention is a thin plate manufacturing apparatus for dipping a substrate held by a substrate transport mechanism into a melt thereby forming a thin plate on the surface of the aforementioned substrate, and the aforementioned substrate transport mechanism includes substrate fixing means for fixing the aforementioned substrate, horizontal movement position control means for controlling a horizontal movement position of the aforementioned substrate fixing means for controlling a horizontal movement position of the surface of the aforementioned substrate with respect to the level of the aforementioned melt, vertical movement position control means for controlling a vertical movement position of the aforementioned substrate fixing means for controlling a vertical movement position of the surface of the aforementioned substrate with respect to the level of the aforementioned melt and substrate inclination means for controlling an inclination of the aforementioned substrate fixing means for inclining the surface of the aforementioned substrate with respect to the level of the aforementioned melt.

Further, the aforementioned horizontal movement position control means has a horizontally extending horizontal guide rail and a horizontal moving unit movably provided along the aforementioned horizontal guide rail, the aforementioned vertical movement position control means has a vertical guide shaft vertically slidably supported in the aforementioned horizontal moving unit so that the aforementioned substrate fixing means is coupled to its lower end and a vertical guide rail provided along the aforementioned horizontal guide rail for guiding a movement position of the upper end of the aforementioned vertical guide shaft, and the aforementioned substrate inclination means has an inclination guide shaft vertically slidably supported in the aforementioned horizontal moving unit so that the aforementioned substrate fixing means is coupled to its lower end and an inclination guide rail provided along the aforementioned horizontal guide rail for guiding the upper end of the aforementioned inclination guide shaft.

This structure is so employed that it is possible to horizontally move the vertical guide shaft and the inclination guide shaft with no dedicated drives by moving the horizontal moving unit along the horizontal guide rail. The directions of movement of the upper ends of the vertical guide shaft and the inclination guide shaft are guided by the vertical guide rail and the inclination guide rail respectively, whereby the positions of the vertical guide shaft and the inclination guide shaft can be decided in a driven manner. Consequently, the substrate transport mechanism can employ a structure of providing only the horizontal movement position control means with a drive without providing the respective ones of the horizontal movement position control means, the vertical movement position control means and the substrate inclination means with drives, whereby the structure of the substrate transport mechanism can be simplified.

A thin plate manufacturing apparatus according to still another aspect of the present invention is a thin plate manufacturing apparatus for dipping a substrate held by a substrate transport mechanism into a melt thereby forming a thin plate on the surface of the aforementioned substrate, and the aforementioned substrate transport mechanism includes substrate fixing means for fixing the aforementioned substrate, horizontal movement position control means for controlling a horizontal movement position of the aforementioned substrate fixing means for controlling a horizontal movement position of the surface of the aforementioned substrate with respect to the level of the aforementioned melt, vertical movement position control means for controlling a vertical movement position of the aforementioned substrate fixing means for controlling a vertical movement position of the surface of the aforementioned substrate with respect to the level of the aforementioned melt and substrate inclination means for controlling an inclination of the aforementioned substrate fixing means for inclining the surface of the aforementioned substrate with respect to the level of the aforementioned melt.

Further, the aforementioned horizontal movement position control means has a horizontally extending horizontal/vertical guide rail and a horizontal moving unit movably provided along the aforementioned horizontal/vertical guide rail, the aforementioned vertical movement position control means has a vertical guide shaft having an upper end coupled to the aforementioned horizontal moving unit and a lower end coupled with the aforementioned substrate fixing means, and the aforementioned substrate inclination means has an inclination guide shaft vertically slidably supported so that the aforementioned substrate fixing means is coupled to its lower end and an inclination guide rail provided along the aforementioned horizontal/vertical guide rail for guiding the upper end of the aforementioned vertical shaft.

This structure is so employed that it is possible to horizontally move the vertical guide shaft and the inclination guide shaft with no dedicated drives by moving the horizontal moving unit along the horizontal/vertical guide rail. Further, the upper end of the vertical guide shaft is coupled to the horizontal moving unit, whereby the position of the vertical guide shaft can be decided in a driven manner by controlling the trajectory of the horizontal/vertical guide rail. In addition, the direction of movement of the upper end of the inclination guide shaft is guided by the inclination guide rail, whereby the position of the inclination guide shaft can also be decided in a driven manner.

Consequently, the substrate transport mechanism can employ a structure of providing only the horizontal movement position control means with a drive without providing the respective ones of the horizontal movement position control means, the vertical movement position control means and the substrate inclination means with drives, whereby the structure of the substrate transport mechanism can be simplified.

A thin plate manufacturing apparatus according to a further aspect of the present invention is a thin plate manufacturing apparatus for dipping a substrate held by a substrate transport mechanism into a melt thereby forming a thin plate on the surface of the aforementioned substrate, and the aforementioned substrate transport mechanism includes substrate fixing means for fixing the aforementioned substrate, horizontal movement position control means for controlling a horizontal movement position of the aforementioned substrate fixing means for controlling a horizontal movement position of the surface of the aforementioned substrate with respect to the level of the aforementioned melt, vertical movement position control means for controlling a vertical movement position of the aforementioned substrate fixing means for controlling a vertical movement position of the surface of the aforementioned substrate with respect to the level of the aforementioned melt and substrate inclination means for controlling an inclination of the aforementioned substrate fixing means for inclining the surface of the aforementioned substrate with respect to the level of the aforementioned melt.

Further, the aforementioned horizontal movement position control means has a horizontally extending horizontal/vertical/inclination guide rail and a horizontal moving unit movably provided along the aforementioned horizontal rail, the aforementioned vertical movement position control means has a vertical guide shaft having an upper end coupled to the aforementioned horizontal moving unit and a lower end coupled with the aforementioned substrate fixing means, and the aforementioned substrate inclination means has an inclination guide shaft having an upper end coupled to the aforementioned horizontal moving unit and a lower end coupled with the aforementioned substrate fixing means.

This structure is so employed that it is possible to horizontally move the vertical guide shaft and the inclination guide shaft with no dedicated drives by moving the horizontal moving unit along the horizontal/vertical inclination guide rail. Further, the upper ends of the vertical guide shaft and the inclination guide shaft are coupled to the horizontal moving unit respectively, whereby the positions of the vertical guide shaft and the inclination guide shaft can also be decided in a driven manner by controlling the trajectory of the horizontal/vertical/inclination guide rail.

Consequently, the substrate transport mechanism can employ a structure of providing only the horizontal movement position control means with a drive without providing the respective ones of the horizontal movement position control means, the vertical movement position control means and the substrate inclination means with drives, whereby the structure of the substrate transport mechanism can be simplified.

A thin plate manufacturing apparatus according to a further aspect of the present invention is a thin plate manufacturing apparatus for dipping a substrate held by a substrate transport mechanism into a melt thereby forming a thin plate on the surface of the aforementioned substrate, and the aforementioned substrate transport mechanism includes substrate fixing means for fixing the aforementioned substrate, horizontal movement position control means for controlling a horizontal movement position of the aforementioned substrate fixing means for controlling a horizontal movement position of the surface of the aforementioned substrate with respect to the level of the aforementioned melt, vertical movement position control means for controlling a vertical movement position of the aforementioned substrate fixing means for controlling a vertical movement position of the surface of the aforementioned substrate with respect to the level of the aforementioned melt and substrate inclination means for controlling an inclination of the aforementioned substrate fixing means for inclining the surface of the aforementioned substrate with respect to the level of the aforementioned melt.

Further, the aforementioned horizontal movement position control means has a horizontally extending horizontal guide rail and a horizontal moving unit movably provided along the aforementioned horizontal rail, the aforementioned vertical movement position control means has a vertical guide shaft vertically slidably supported in the aforementioned horizontal moving unit so that the aforementioned substrate fixing means is coupled to its lower end and a vertical/inclination guide rail provided along the aforementioned horizontal rail for guiding a movement position of the upper end of the aforementioned vertical guide shaft, and the aforementioned substrate inclination means has an inclination guide shaft vertically slidably supported in the aforementioned horizontal moving unit so that the aforementioned substrate fixing means is coupled to its lower end and a movement position of its upper end is guided by the aforementioned vertical/inclination guide rail.

This structure is so employed that it is possible to horizontally move the vertical guide shaft and the inclination guide shaft with no dedicated drives by moving the horizontal moving unit along the horizontal guide rail. Further, the directions of movement of the upper ends of the vertical guide shaft and the inclination guide shaft are guided by the vertical/inclination guide rail respectively, whereby the positions of the vertical guide shaft and the inclination guide shaft can be decided in a driven manner. Consequently, the substrate transport mechanism can employ a structure of providing only the horizontal movement position control means with a drive without providing the respective ones of the horizontal movement position control means, the vertical movement position control means and the substrate inclination means with drives, whereby the structure of the substrate transport mechanism can be simplified.

Preferably in the aforementioned invention, the thin plate manufacturing apparatus further comprises substrate temperature control means for controlling the temperature on the surface of the aforementioned substrate before dipping the aforementioned substrate into the aforementioned melt. This structure is so employed that it is possible to optimize the temperature on the surface of the substrate when forming the thin plate on the surface of the substrate.

### BRIEF DESCRIPTION OF THE DRAWINGS

FIG. 1 is a schematic diagram showing the overall structure of a thin plate manufacturing apparatus according to a first embodiment.

FIG. 2 is an enlarged view of a substrate transport mechanism 1.

FIG. 3 partially illustrates a control block of the thin plate manufacturing apparatus according to the first embodiment.

FIG. 4 is a schematic diagram showing a method of detaching a silicon polycrystalline thin plate 3 grown from a substrate 2.

FIG. 5 is a schematic diagram showing trajectory steps of the substrate 2 for growing the silicon polycrystalline thin plate 3.

FIG. 6 is a schematic diagram showing the overall structure of a thin plate manufacturing apparatus according to a second embodiment.

FIG. 7 is a schematic diagram showing the overall structure of a thin plate manufacturing apparatus according to a third embodiment.

FIG. 8 illustrates dripping heights, solar cell prototype yields and solar cell efficiencies of solar cell prototypes prepared with silicon polycrystalline thin plates 3 according to the first to fourth embodiments and a background technique.

FIG. 9 is a schematic diagram showing fourth and fifth steps in trajectory steps of a substrate 2 for growing a silicon polycrystalline thin plate 3 in a sixth embodiment.

FIG. 10 illustrates numbers of projections, solar cell prototype yields and solar cell efficiencies of solar cell prototypes prepared with the silicon polycrystalline thin plate 3 according to the sixth embodiment.

FIG. 11 is a schematic diagram showing the overall structure of a thin plate manufacturing apparatus according to an eighth embodiment.

FIG. 12 is an enlarged view of a substrate transport mechanism 1 in the eighth embodiment.

FIG. 13 illustrates the trajectory of the substrate transport mechanism 1 in the eighth embodiment.

FIG. 14 is a schematic diagram showing the overall structure of a thin plate manufacturing apparatus according to a ninth embodiment.

FIG. 15 illustrates the trajectory of a substrate transport mechanism 1 in the ninth embodiment.

FIG. 16 is a schematic diagram showing the overall structure of a thin plate manufacturing apparatus according to a tenth embodiment.

FIG. 17 illustrates a supply trajectory of a substrate transport mechanism 1 in the tenth embodiment.

FIG. 18 illustrates a return trajectory of the substrate transport mechanism 1 in to the tenth embodiment.

FIG. 19 is a schematic diagram showing the overall structure of a thin plate manufacturing apparatus according to an eleventh embodiment.

FIG. 20 illustrates the trajectory of a substrate transport mechanism 1 in the eleventh embodiment.

FIG. 21 schematically illustrates the structure of a “crystal sheet manufacturing apparatus” disclosed in a background technique.

### BEST MODES FOR CARRYING OUT THE INVENTION

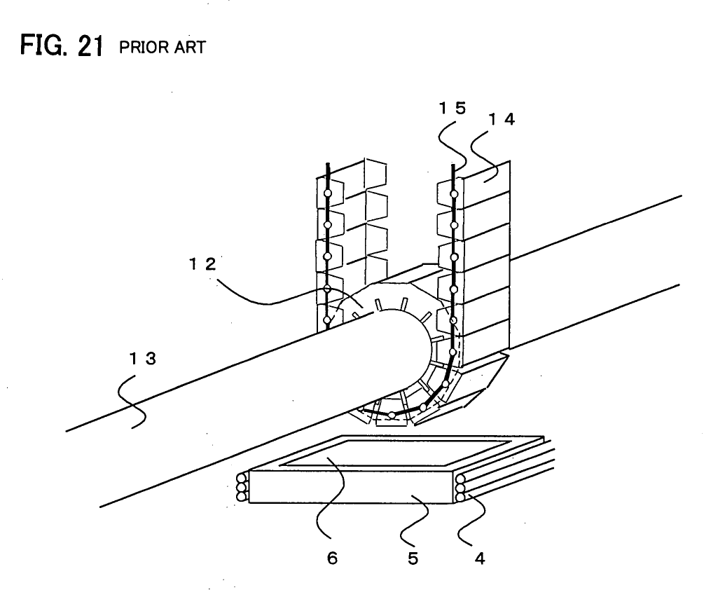

FIG. 21 shows a “crystal sheet manufacturing apparatus” as a background technique for the present invention. In the structure of this “crystal sheet manufacturing apparatus”, a plurality of substrates 14 are guided by a polygonal rotator 12, rotationally dipped into a melt 6 from one side, taken out from the other side of the melt 6 and discharged from the system. The substrates 14 are coupled with each other by a substrate coupler 15 in a caterpillar manner. A rotary shaft 13 is rotation-controlled to a prescribed rotational frequency by an unillustrated rotation driving mechanism, so that the substrates 14 are successively guided into the melt 6 and then discharged. The melt 6 is held in a crucible 5 comprising a heater 4.

According to the “crystal sheet manufacturing apparatus” consisting of this structure, it is possible to solidify/grow crystal sheets consisting of planar unwrapped flat thin plates having no curvature on the substrates 14 by dipping the flat substrates 14 guided by the polygonal rotator 12. Further, it is possible to continuously take out the crystal sheets from the substrates 14 by continuously rotating the polygonal rotator 12.

In the “crystal sheet manufacturing apparatus and a crystal sheet manufacturing method” in the aforementioned background technique, however, the motion of the substrates 14 is limited to rotational motion. Therefore, it is difficult to control growth conditions for growing the thin plates on the substrates 14.

For example, a horizontal traveling speed and a vertical traveling speed of the substrates 14 cannot be separately set. Consequently, an immersion angle for immersing the substrates 14 into the melt 6 cannot be arbitrary set. Further, a route for progressing the substrates 14 through the melt 6 cannot be arbitrarily set. In particular, an escape angle of the substrates 14 escaping from the melt 6 cannot be arbitrarily set.

Consequently, conditions for growing the thin plates on the substrates 14 and control conditions for the correlation between the thin plates and the melt 6 when the substrates 14 escape from the melt 6 cannot be arbitrarily set, and hence it is difficult to optimize the shape of the thin plates. In particular, it is so difficult to control menisci crawling up onto the thin plates when the thin plates escape from the melt 6 that formation of pools on ends of the thin plates disadvantageously result in shape deterioration of the thin plates.

Further, motion of the substrates 14 cannot be arbitrarily set before or after the substrates 14 are immersed in or escape from the melt 6. Thus, a position for separating/taking out the thin plates from the substrates 14 or a position for attaching/detaching the substrates 14 cannot be arbitrarily set but this operation must inevitably be performed on a position above the melt 6. Therefore, a mechanical mechanism part for performing the said operation is so readily thermally effected due to radiation or transfer from the melt 6, the crucible 5 or the heater 4 that the mechanism part is hard to design and it is difficult to improve mass productivity.

Thus, the “crystal sheet manufacturing apparatus and a crystal sheet manufacturing method” in the aforementioned background technique, capable of obtaining flat thin plates, had such problems that it is difficult to optimize the shape of the thin plates and it is also difficult to improve mass productivity due to the rotational motion of the substrates 14.

Thin plate manufacturing apparatuses and thin plate manufacturing methods according to respective embodiments of the present invention for solving the aforementioned problems are now described with reference to the drawings.

(First Embodiment)

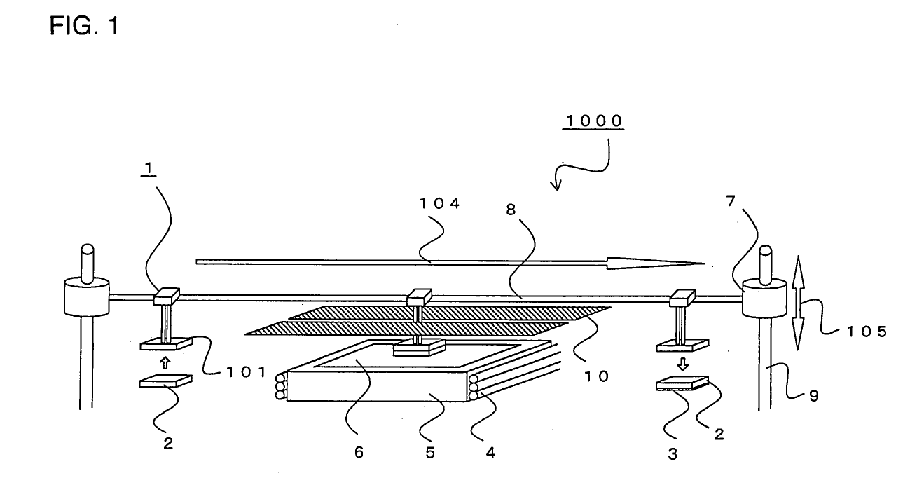

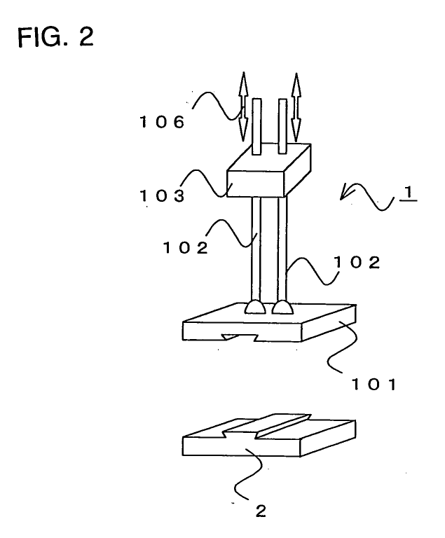

First, a thin plate manufacturing apparatus and a thin plate manufacturing method according to this embodiment are described with reference to FIGS. 1 and 2. FIG. 1 is a schematic diagram showing the overall structure of the thin plate manufacturing apparatus according to this embodiment, and FIG. 2 is an enlarged view of a substrate transport mechanism 1 described later.

(Overall Structure of Thin Plate Manufacturing Apparatus 1000)

The overall structure of a thin plate manufacturing apparatus 1000 according to this embodiment is described with reference to FIG. 1. This thin plate manufacturing apparatus 1000 is in such a structure that a substrate is movable in two directions of a horizontal direction 104 and a vertical direction 105. This thin plate manufacturing apparatus 1000 comprises the substrate transport mechanism 1, and this substrate transport mechanism 1 is provided to be movable in the horizontal direction 104 along a horizontal moving shaft 8. The horizontal moving shaft 8 has a linear rail, and a horizontal movement motor provided in a unit 103 (refer to FIG. 2 described later) provided in the substrate transport mechanism 1 is so employed that the substrate transport mechanism 1 and a substrate 2 held by this substrate transport mechanism 1 are freely movable in the horizontal direction 104.

The horizontal moving shaft 8 is provided to be movable along a vertical moving shaft 9. The horizontal moving shaft 8 is coupled to a vertical movement motor 7. It is possible to freely move the horizontal moving shaft 8 coupled to the vertical movement motor 7, the substrate transport mechanism 1 provided on the horizontal moving shaft 8 and the substrate 2 held by the substrate transport mechanism 1 in the vertical direction 105 by forming the vertical moving shaft 9 by a toothed linear rail and operating the vertical movement motor 7. Consequently, the substrate 2 can freely move in a plane defined by the horizontal moving shaft 8 and the vertical moving shaft 9. For the movement, it is also possible to operate either or both of the horizontal moving shaft 8 and the vertical moving shaft 9 as mechanisms such as ball screws.

A crucible 5 for holding a melt 6 and a heating mechanism 4 for heating the melt 6 are arranged under the horizontal moving shaft 8. A thermal shield mechanism 10 is arranged above the melt 6, in order to insulate a substrate fixing member 101 (described later) and the unit 103 (described later) from the melt 6. An apparatus or a member rich in thermal insulation property such as a water-cooled metal plate or a heat-resistant insulation board is employed for this thermal shield mechanism 10. Thus, it is possible to avoid thermal rupture of the mechanism resulting from a thermal effect on the substrate fixing member 101 (described later) and the unit 103 (described later) or precision loss based on linearity deterioration of the horizontal moving shaft 8 resulting from thermal expansion.

(Detailed Structure of Substrate Transport Mechanism 1)

The detailed structure of the substrate transport mechanism 1 is now described with reference to FIG. 2. According to this embodiment, two substrate inclination shafts 102 are connected to the unit 103 including a horizontal movement motor and an inclination motor in the substrate transport mechanism 1. The two substrate inclination shafts 102 are independently vertically moved (in directions shown by arrows 106 in FIG. 2) respectively, so that the substrate fixing member 101 connected to the lower portions thereof can be inclined.

This embodiment employs a mechanism providing mutual engagement by convexo-concave shapes as an attaching/detaching mechanism for the substrate 2 and the substrate fixing member 101. Alternatively, another well-known attaching/detaching function is applicable to this mechanism. In order to attach the substrate 2 to the substrate fixing member 101 or detach the substrate 2 from the substrate fixing member 101, the attaching/detaching mechanism (not shown) is set on a position separated from the heating mechanism 4.

The substrate 2 is desirably made of carbon, SiC or a high-melting point metal or a material prepared by coating this material with another substance as a material having excellent heat resistance and not contaminating a grown thin plate 3. A carbon substrate was employed in this embodiment. Further, the surface of the substrate 2 for growing the thin plate 3 was rendered planar. However, this plane may not necessarily be completely smooth but the surface may be specifically shaped.

In addition, the thin plate 3 solidified/grown from the melt 6 may exhibit a single-crystalline state, a polycrystalline state, an amorphous state or a crystalline state of a substance exhibiting crystalline and amorphous states in a mixed manner depending on conditions such as the temperature.

It is possible to use a semiconductor material such as silicon, germanium, gallium, arsenic, indium, phosphorus, boron, antimony, zinc or tin or a metallic material such as aluminum, nickel or iron for the melt 6.

(Control of Thin Plate Manufacturing Apparatus 1000 and Thin Plate Manufacturing Method)

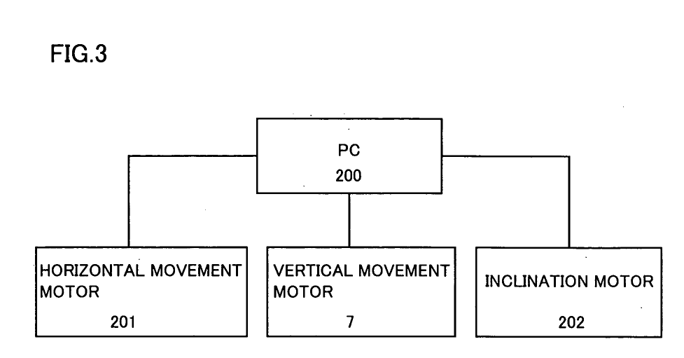

In order to operate the substrate transport mechanism 1, a PC 200 transmits different operation patterns to a horizontal movement motor 201, the vertical movement motor 7 and an inclination motor 202 for independently controlling the horizontal movement motor 201, the vertical movement motor 7 and the inclination motor 202 respectively, as shown in FIG. 3. The operation patterns of the horizontal movement motor 201, the vertical movement motor 7 and the inclination motor 202 are automatically or manually switched with parameters such as time and temperature. Thus, it is possible to control the trajectory of the substrate 2 to attain the object by independently controlling the horizontal movement motor 201, the vertical movement motor 7 and the inclination motor 202 respectively. Further, it is also possible to select control of performing only horizontal movement (with no vertical movement or inclination) in an interval immediately preceding the operation of dipping the substrate 2 into the melt 6 and an interval immediately following the operation of dipping the substrate 2 into the melt 6.

Control of the thin plate manufacturing apparatus 1000 and the thin plate manufacturing method are now described with reference to the case of employing a silicon melt as the melt 6 for manufacturing the silicon polycrystalline thin plate 3 from this silicon melt 6. Referring to FIG. 1, the substrate 2 is attached to the substrate transport mechanism 1 on a position separated from the silicon melt 6. Then, the horizontal movement motor 201 is driven for transporting the substrate 2 to a position immediately above the silicon melt 6 with the substrate transport mechanism 1, and the horizontal movement motor 201 and the vertical movement motor 7 are independently driven respectively thereby providing the substrate 2 with an arbitrary trajectory and dipping the substrate 2 into the silicon melt 6. Then, the substrate 2 is taken out from the silicon melt 6, thereby growing the silicon polycrystalline thin plate 3 on the substrate 2. When the substrate 2 is dipped into and taken out from the silicon melt 6, the inclination motor 202, the horizontal movement motor 201 and the vertical movement motor 7. are independently controlled respectively for supplying the substrate 2 with prescribed inclination.

Thereafter the horizontal movement motor 201 and the vertical movement motor 7 are employed for transporting the substrate 2 having the silicon polycrystalline thin plate 3 grown thereon to a position separated from the silicon melt 6. Thereafter the substrate 2 is detached from the substrate transport mechanism 1, for obtaining the grown silicon polycrystalline thin plate 3 from the substrate 2.

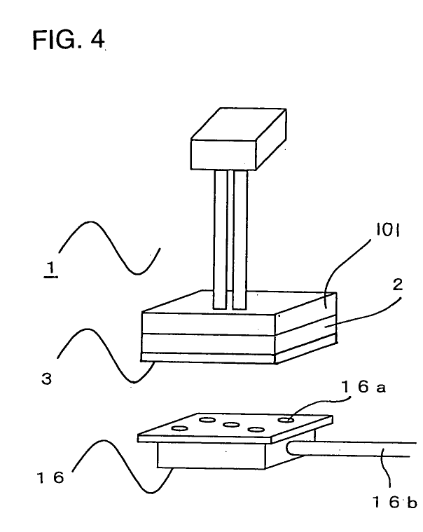

In order to detach the grown silicon polycrystalline thin plate 3 from the substrate 2 without detaching the substrate 2 from the substrate transport mechanism 1, the substrate transport mechanism 1 transports the substrate 2 onto a stage 16 having a plurality of suction holes 16a for vacuum-sucking the silicon polycrystalline thin plate 3 through the suction holes 16a, as shown in FIG. 4. Thereafter an arm 16b provided on the stage 16 moves the stage 16 sucking/holding the silicon polycrystalline thin plate 3 to a thin plate stocking position or an external discharge mechanism for detaching the silicon polycrystalline thin plate 3 from the stage 16. The series of operations for detaching the silicon polycrystalline thin plate 3 are performed in time with the movement of the substrate transport mechanism 1.

(Trajectory Step of Substrate 2)

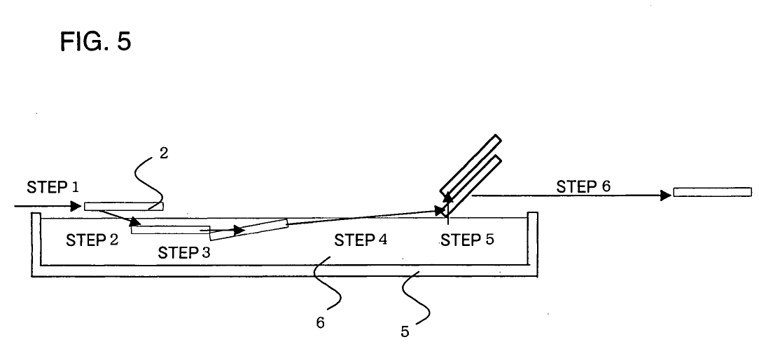

Specific trajectory steps of the substrate 2 for growing the silicon polycrystalline thin plate 3 in this embodiment are now described with reference to FIG. 5.

First Step: The horizontal movement motor 201 and the vertical movement motor 7 are controlled for moving the substrate 2 to a position immediately above the level of the silicon melt 6 by 10 mm. At this time, an inclination (an angle with respect to a horizontal plane) of the substrate 2 is horizontally set.

Second Step: The horizontal movement motor 201 and the vertical movement motor 7 are controlled for controlling a horizontal traveling speed and a vertical traveling speed constant (100 mm/sec. and 50 mm/sec. respectively) after the forward end of the substrate 2 starts dipping and before the substrate 2 dips by 20 mm from the level of the silicon melt 6. The inclination of the substrate 2 is kept horizontal (constant).

Third Step: The horizontal movement motor 201 and the vertical movement motor 7 are so controlled that the horizontal traveling speed reaches 500 mm/sec. and the vertical traveling speed reaches 0 mm/sec. when the substrate 2 dips by 20 mm from the level of the silicon melt 6, for horizontally moving the substrate 2 by 10 mm.

Fourth Step: Then, the inclination motor 202 is so controlled that the traveling direction side of the substrate 2 is upward and the inclination of the substrate reaches 100. The horizontal movement motor 201 and the vertical movement motor 7 are so controlled that the horizontal traveling speed and the vertical traveling speed are constant (100 mm/sec. and 10 mm/sec. respectively), for taking out the substrate 2 from the silicon melt 6.

Fifth Step: The inclination motor 202 is so controlled that the inclination of the substrate reaches 45° when the end of the substrate 2 escapes. Thereafter the vertical movement motor 7 is controlled for vertically moving up the substrate 2 by 30 mm at 100 mm/sec.

Sixth Step: Then, the inclination motor 202 is controlled for returning the substrate 2 to a horizontal state, and the horizontal movement motor 201 is controlled for transporting the substrate 2 to a takeout position.

The size of the substrate 2 is 100 mm square, and the time for dipping the substrate 2 into the silicon melt 6 is about 4 seconds. The time for attaching the substrate 2 to the substrate transport mechanism 1 was about 5 seconds, the time for moving the substrate 2 from the attaching position to a dipping position was 3 seconds, the dipping time was 4 seconds, the time for moving the substrate 2 to the takeout position was 3 seconds, the time for detaching the substrate 2 from the substrate transport mechanism 1 was about 5 seconds, and the time for returning the substrate transport mechanism 1 from the takeout position to the attaching position was 9 seconds. Consequently, the time necessary for the series of steps is about 29 seconds (5 seconds+3 seconds+4 seconds+3 seconds+5 seconds+9 seconds). However, the return time can be reduced through a device of identically setting the substrate attaching position and the detaching position or providing a substrate attaching mechanism and a detaching mechanism on both sides of the heating mechanism 4, so that the time necessary for the series of steps is about 20 seconds.

(Functions/Effects)

According to the silicon polycrystalline thin plate 3 manufactured with the thin plate manufacturing apparatus and the thin plate manufacturing method according to this embodiment, as hereinabove described, it was possible to reduce a dripping of about 4 mm in height formed on the end of the silicon polycrystalline thin plate 3, which was caused in a conventional manufacturing method, to about 1 mm. This is because the angle between the substrate 2 and the silicon melt 6 was increased when the substrate 2 was taken out from the silicon melt 6 so that the silicon melt 6 readily flowed down and the quantity of the dripping was reduced.

Therefore, it is possible to freely set the trajectory of the substrate 2 in the plane defined by the horizontal moving shaft 8 and the vertical moving shaft 9 by independently controlling the horizontal movement motor 201, the vertical movement motor 7 and the inclination motor 202 respectively, as hereinabove described. Further, it is possible to control the correlation (angle) between the surface of the substrate 2 and the level of the silicon melt 6 by controlling the two substrate inclination shafts 102 with the inclination motor 202 so that the inclination of the substrate 2 is independently controllable, whereby the inclination of the substrate 2 with respect to the surface of the silicon melt 6 can be optimized when the substrate 2 escapes from the silicon melt 6.

Thus, the correlation between the substrate 2 (and the silicon polycrystalline thin plate 3 grown on the substrate 2) and the silicon melt 6 is so optimized that it is possible to attain improvement of the quality of the silicon polycrystalline thin plate 3, improvement of the shape of the silicon polycrystalline thin plate 3 and improvement of mass productivity of the silicon polycrystalline thin plate 3.

Further, the substrate transport mechanism 1 employs the structure capable of attaching/detaching the substrate 2 to/from the substrate transport mechanism 1, whereby it is possible to continuously use the substrate transport mechanism 1 while exchanging only the substrate 2 when the durability of the substrate 2 is finite, and there is no need to exchange the overall substrate transport mechanism 1 but it is possible to prevent rise of the labor, the time and the cost.

In addition, the substrate 2 can be attached/detached to/from the substrate transport mechanism 1 on a position other than that above the crucible 5, whereby it is possible to avoid a bad thermal influence such as thermal rupture of the substrate attaching/detaching mechanism 1 resulting from heat transfer from the crucible 5 to the substrate attaching/detaching mechanism 1 or a possibility of precision loss resulting from thermal expansion.

Considering mass production of continuously producing the silicon polycrystalline thin plate 3, it is possible to readily set a movement pattern and an inclination pattern of the substrate 2 to optimum patterns with time against such factors that the quantity of the silicon melt 6 (the absolute position of the height of the melt or the like) changes with time and the in-apparatus atmosphere changes with time, for example, by enabling the apparatus to control attachment/detachment independently of the movement and the inclination of the substrate 2 in response to aging of the substrate 2 also as to attachment/detachment of the substrate 2.

(Second Embodiment)

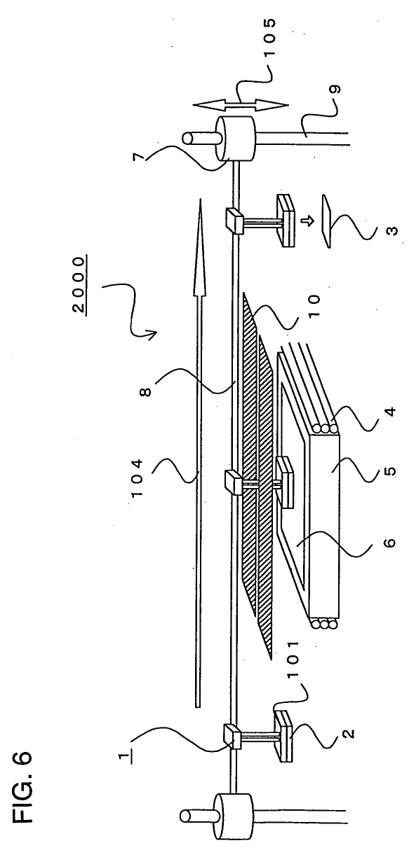

A thin plate manufacturing apparatus and a thin plate manufacturing method according to this embodiment are now described with reference to FIG. 6. FIG. 6 is a schematic diagram showing the overall structure of a thin plate manufacturing apparatus 2000 according to this embodiment.

The basic structure of the thin plate manufacturing apparatus 2000 according to this embodiment is identical to that of the thin plate manufacturing apparatus 1000 according to the first embodiment. The thin plate manufacturing apparatus 2000 is different from the thin plate manufacturing apparatus 1000 in a point that the same separates and recovers only a thin plate 3 from a substrate 2 without attaching and detaching the substrate 2 to and from a substrate transport mechanism 1. Therefore, the structure of the thin plate manufacturing apparatus 2000 is basically identical to that of the aforementioned thin plate manufacturing apparatus 1000, and hence identical portions in FIG. 6 are denoted by the same reference numerals, and redundant description is not repeated as to the thin plate manufacturing apparatus 2000. The detailed structure of the substrate transport mechanism 1 is also identical to that of the substrate transport mechanism 1 applied to the aforementioned thin plate manufacturing apparatus 1000, and hence redundant description is not repeated.

According to this embodiment, the thin plate 3 was manufactured through a series of operations of transporting the substrate 2 attached to the substrate transport mechanism 1 to a position immediately above a melt 6, dipping the substrate 2 into the melt 6 along an arbitrary trajectory similarly to the first embodiment, then taking out the substrate 2 from the melt 6 thereby growing the thin plate 3 on the substrate, transporting the substrate 2 and the thin plate 3 to a takeout position and detaching only the thin plate 3 from the substrate 2.

(Control of Thin Plate Manufacturing Apparatus 2000 and Thin Plate Manufacturing Method)

Control of the thin plate manufacturing apparatus 2000 and the thin plate manufacturing method are basically identical to the control of the thin plate manufacturing apparatus 1000 and the thin plate manufacturing method, and a silicon polycrystalline thin plate 3 was manufactured. Trajectory steps of the substrate 2 are also similar to the steps described with reference to FIG. 5, while a step of separating and recovering only the silicon polycrystalline thin plate 3 from the substrate 2 without attaching and detaching the substrate 2 to and from the substrate transport mechanism 1 is different.

Therefore, no time was required for attaching and detaching the substrate 2, while a dipping time was about 4 seconds, a movement time for transporting the substrate to the takeout position was 3 seconds, the time for detaching the thin plate 3 from the substrate 2 was about 5 seconds, and a return time from the detaching position to a dipping position was 6 seconds. Therefore, the time necessary for the series of steps is about 18 seconds (4 seconds +3 seconds +5 seconds +6 seconds).

(Functions/Effects)

According to the thin plate manufacturing apparatus and the thin plate manufacturing method of this embodiment, as hereinabove described, functions/effects similar to those of the aforementioned first embodiment can be attained. Further, the step of detaching and recovering only the silicon polycrystalline thin plate 3 from the substrate 2 without attaching and detaching the substrate 2 to and from the substrate transport mechanism 1 is so employed that no time is required for attaching and detaching the substrate 2 but it is possible to reduce the manufacturing time for the silicon polycrystalline thin plate 3.

(Third Embodiment)

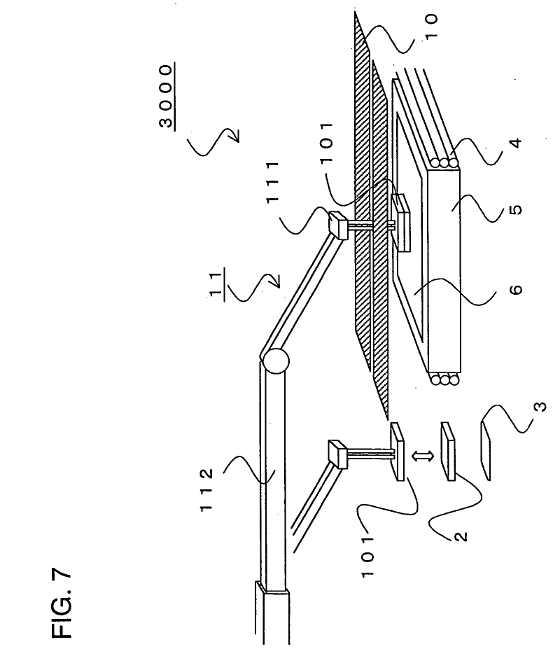

A thin plate manufacturing apparatus and a thin plate manufacturing method according to this embodiment are now described with reference to FIG. 7. FIG. 7 is a schematic diagram showing the overall structure of a thin plate manufacturing apparatus 3000 according to this embodiment. The thin plate manufacturing apparatus 3000 according to this embodiment is in a structure capable of freely moving a substrate 2 in a three-dimensional space including a horizontal direction and a vertical direction. Portions identical to those of the aforementioned thin plate manufacturing apparatus 1000 are denoted by the same reference numerals, and redundant description is not omitted. A mechanism similar to the mechanism shown in FIG. 2 described with reference to the first embodiment is employed also as to an in inclination mechanism provided on the forward end of a free-arm type substrate transport mechanism 11 for inclining the substrate 2, and hence redundant description is not repeated.

The substrate transport mechanism 11 in this embodiment has a telescopic arm 112 having a telescopic mechanism, for enabling horizontal movement of the substrate 2 at a high speed and over a wide range with this telescopic arm 112. It is possible to freely move the telescopic arm 112 in the three-dimensional space by combining an arm operation mechanism (not shown) on a support side of the telescopic arm 112.

Inclination of the substrate 2 and fine vertical and horizontal operations are performable through a joint provided on an intermediate position of the telescopic arm 112 and a joint between a substrate inclination motor 111 provided on the forward end of the telescopic arm 112 and the telescopic arm 112. Further, it is possible to adjust the inclination of the substrate by an operation of a substrate inclination shaft, similarly to the first embodiment.

A thermal shield mechanism 10 is desirably set above a heating mechanism 4, a crucible 5 and a melt 6 in order to prevent heat transfer toward a substrate fixing member 101 and the substrate inclination motor 111, similarly to the first embodiment. A water-cooled metal plate or a heat-resistant insulation board is employed for the thermal shield mechanism 10, similarly to the first embodiment. Thus, it is possible to avoid thermal rupture of the mechanism resulting from a thermal effect on the substrate fixing member 101, the substrate inclination motor 111 and the telescopic arm 112 or precision loss based on linearity deterioration of a horizontal moving shaft 8 resulting from thermal expansion.

A position for attaching or detaching the substrate 2 to or from the substrate transport mechanism 11 is desirably set in the vicinity of the bottom of the telescopic arm 112, not to increase the length of the telescopic arm 112 beyond necessity. In this embodiment, therefore, a mechanism for. attaching/detaching the substrate 2 to/from the substrate transport mechanism 11 was provided on the bottom of the telescopic arm 112.

(Control of Thin Plate Manufacturing Apparatus 3000 and Thin Plate Manufacturing Method)

Control of the thin plate manufacturing apparatus 3000 and the thin plate manufacturing method are basically identical to the control of the thin plate manufacturing apparatus 1000 and the thin plate manufacturing method, and a silicon polycrystalline thin plate 3 was manufactured. Trajectory steps of the substrate 2 are also similar to the steps described with reference to FIG. 5.

In the case of this embodiment, a time for attaching the substrate 2 was about 5 seconds, a time for moving the substrate 2 from an attaching/detaching position to a position for dipping the same into a silicon melt 6 was 3 seconds, a dipping time was 4 seconds, a return time for the substrate 2 to the attaching/detaching position was 6 seconds, and a time for detaching the substrate 2 was about 5 seconds. Therefore, the time necessary for the series of steps is about 23 seconds (5 seconds+3 seconds+4 seconds+6 seconds+5 seconds).

(Functions/Effects)

According to the thin plate manufacturing apparatus and the thin plate manufacturing method of this embodiment, as hereinabove described, functions/effects similar to those of the aforementioned first embodiment can be attained.

(Fourth Embodiment)

A thin plate manufacturing apparatus and a thin plate manufacturing method according to this embodiment are now described. The basic structure of the thin plate manufacturing apparatus according to this embodiment is identical to that of the thin plate manufacturing apparatus 3000 according to the third embodiment shown in FIG. 7. The point different from the third embodiment is that only a thin plate 3 is separated and recovered from a substrate 2 without attaching and detaching the substrate 2 to and from a substrate transport mechanism 1.

According to this embodiment, the thin plate 3 was manufactured through a series of operations of transporting the substrate 2 attached to the substrate transport mechanism 1 to a position immediately above a melt 6, dipping the substrate 2 into the melt 6 along an arbitrary trajectory similarly to the first embodiment, then taking out the same from the melt 6 thereby growing the thin plate 3 on the substrate, transporting the substrate 2 and the thin plate 3 to a takeout position and detaching only the thin plate 3 from the substrate 2.

(Control of Thin Plate Manufacturing Apparatus and Thin Plate Manufacturing Method)

Control of the thin plate manufacturing apparatus and the thin plate manufacturing method are basically identical to the control of the thin plate manufacturing apparatus 3000 and the thin plate manufacturing method, and a silicon polycrystalline thin plate 3 was manufactured. Trajectory steps of the substrate 2 are also similar to the steps described with reference to FIG. 5, while a step of separating and recovering only the silicon polycrystalline thin plate 3 from the substrate 2 without attaching and detaching the substrate 2 to and from the substrate transport mechanism 1 is different.

Therefore, no time was required for attaching and detaching the substrate 2, while a time for moving the substrate 2 from an attaching/detaching position to a dipping position for the substrate 2 was about 3 seconds, a dipping time for the substrate 2 was about 4 seconds, a return time for the substrate 2 to the attaching/detaching position was about 6 seconds, and a time for detaching the silicon polycrystalline thin plate 3 was about 5 seconds. Therefore, the time necessary for the series of steps is about 18 seconds (3 seconds+4 seconds+6 seconds+5 seconds).

(Functions/Effects)

According to the thin plate manufacturing apparatus and the thin plate manufacturing method of this embodiment, as hereinabove described, functions/effects similar to those of the aforementioned third embodiment can be attained. Further, the step of detaching and recovering only the silicon polycrystalline thin plate 3 from the substrate 2 without attaching and detaching the substrate 2 to and from the substrate transport mechanism 1 is so employed that no time is required for attaching and detaching the substrate 2 but it is possible to reduce the manufacturing time for the silicon polycrystalline thin plate 3.

(Fifth Embodiment)

Solar cells were prototyped with silicon thin plates prepared according to the thin plate manufacturing apparatuses and the thin plate manufacturing methods described in the above first to fourth embodiments and a thin plate manufacturing apparatus and a thin plate manufacturing method in a background technique shown in FIG. 21.

Prototype processes performed on the silicon thin plates are a first process: cleaning, a second process: texture etching, third process: P diffusion, fourth process: back etching, fifth process: antireflection coating, sixth process: formation of back electrode, seventh process: formation of front electrode, and eighth process: provision of lead.

In the thin plate manufacturing apparatus in the background technique shown in FIG. 21, a substrate 14 was formed by a carbon substrate. The surface of the substrate 14 for growing a silicon polycrystalline thin plate 3 was rendered planar. As a manufacturing process, the substrate was set to 100 mm square, and a polygonal rotator 12 was so designed that the distance between surfaces of the polygonal rotator 12+the substrate 14 (the radius of gyration of the substrate center) was 400 mm.

As to conditions for dipping the substrate 14, the maximum dipping depth was set to 20 mm and the dipping time was set to 4 seconds, in order to approach the conditions to the dipping depth (20 mm) and the dipping time (4 seconds) described in each of the aforementioned embodiments. The substrate 14 is continuously guided and hence a time necessary for a series of steps is 4 seconds substantially similarly to the dipping time. In the prepared silicon polycrystalline thin plate 3, the height of a dripping formed on an end when the substrate 14 escaped from the melt was about 4 mm. This is because the angle between the surface of the substrate and the surface of the melt was regularly low and a liquid hardly flowed down to increase the volume of the dripping due to nonpresence of means for controlling an inclination of the substrate 14 immediately after escape.

While it is possible to control certain thin plate growth conditions and the correlation between the substrate and the melt by setting the dipping depth and a rotational frequency, dipping motion of the substrate was not arbitrarily controllable and hence a pool remained on the substrate.

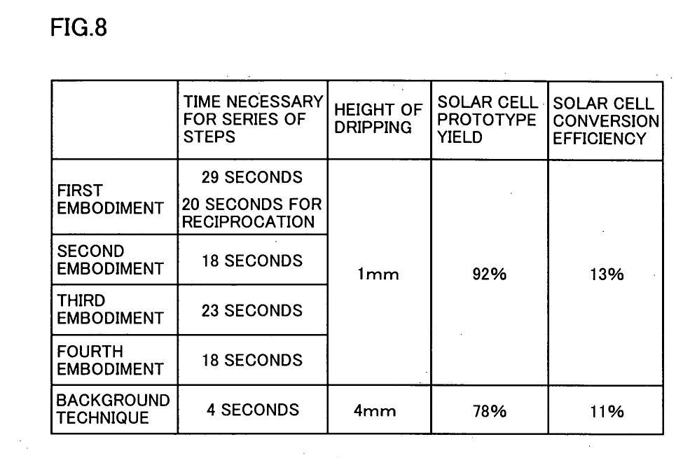

FIG. 8 shows dripping heights, yields in the solar cell prototypes and solar cell conversion efficiencies in the respective embodiments. In the silicon polycrystalline thin plates 3 in the first to fourth embodiments, it was possible to uniformly perform printing in formation of electrodes due to the small drippings of 1 mm. In the silicon polycrystalline thin plate 3 prepared according to the background technique, however, a screen was broken and electrodes were partially bled or disconnected due to influences by the dripping. The efficiency percentage (solar cell prototype yield) at the time of prototyping a solar cell with the silicon polycrystalline thin plate 3 according to the background technique is at a low level of 78% due to breakage of the screen and disconnection of the electrodes. In the silicon polycrystalline thin plates 3 according to the embodiments suppressing drippings, on the other hand, it was possible to improve the yields to 92%. While the solar cell conversion efficiency at the time of prototyping a solar cell with the silicon polycrystalline thin plate 3 according to the background technique is at a low level of 11% due to an influence by bleeding of the electrodes, it was possible to improve the efficiencies to 13% in the silicon polycrystalline thin plates 3 according to the embodiments suppressing the drippings.

(Sixth Embodiment)

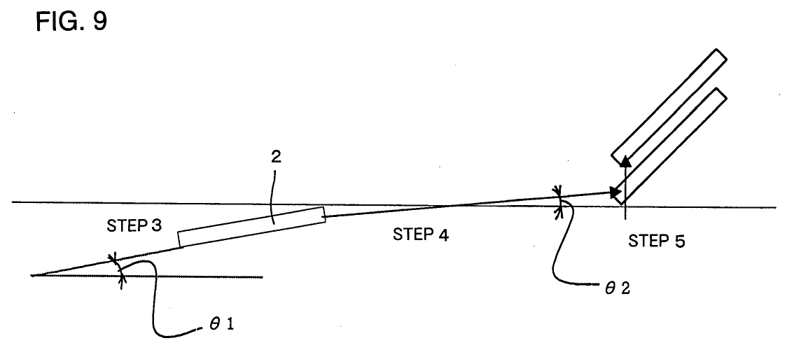

A thin plate manufacturing apparatus and a thin plate manufacturing method according to this embodiment are now described with reference to FIG. 9. FIG. 9 is a schematic diagram showing trajectory steps of a substrate 2 in the case of employing the thin plate manufacturing apparatus according to this embodiment.

The structure of the thin plate manufacturing apparatus according to this embodiment is identical to that of the thin plate manufacturing apparatus 1000 according to the first embodiment. The point different from the first embodiment resides in an inclination of the substrate 2 taken out from a melt 6. Therefore, only the trajectory steps of the substrate 2 in this embodiment are now described.

(Trajectory Step of Substrate 2)

First, the substrate 2 is dipped into the silicon melt 6 by control similar to the first to third steps among the trajectory steps of the substrate 2 shown in FIG. 5. Thereafter the following trajectory steps shown in FIG. 9 are employed.

Fourth Step: An inclination motor 202 is so controlled that the traveling direction side of the substrate 2 is upward and the inclination of the substrate is [θ1°]. A horizontal movement motor 201 and a vertical movement motor 7 are so controlled that a horizontal traveling speed and a vertical traveling speed are constant (100 mm/sec. and 10 mm/sec. respectively), and the substrate 2 is taken out from the silicon melt 6.

Fifth Step: The inclination motor 202 is so controlled that the inclination of the substrate is 45° when an end escapes. Thereafter the vertical movement motor 7 is controlled to vertically move up the substrate 2 by 30 mm at 100 mm/sec.

Sixth Step: Similarly to the trajectory steps of the substrate 2 shown in FIG. 5, the inclination motor 202 is controlled to return the substrate 2 to a horizontal state, and the horizontal movement motor 201 is controlled to transport the substrate 2 to a takeout position. Referring to FIG. 9, θ2 is 5.7°. In this case, θ2 denotes an angle formed between a motion vector of the substrate and the surface of the melt. The size of the substrate 2 is 100 mm square, similarly to that in the first embodiment.

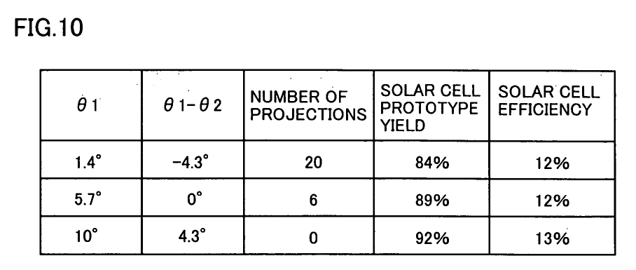

Dipping steps were carried out as to the cases of three patterns of the aforementioned substrate inclination [θ1°] of 1.4° (substantially horizontal), 5.7° (parallel to the motion vector of the substrate) and 10° (similarly to the first embodiment) for comparing the numbers of projections formed on the surface of the silicon polycrystalline thin plate 3. FIG. 10 shows the results.

As clearly understood from FIG. 10, the number of projections formed on the surface of the silicon polycrystalline thin plate 3 increases as the substrate inclination [θ1°] decreases (approaches a horizontal state). This is conceivably based on the following reasons:

When θ1<θ2, the substrate 2 escapes while pulling the melt 6 when the surface of the substrate 2 goes out from the silicon melt 6 (a meniscus position (the interface between the melt and the substrate) progresses oppositely to the traveling direction of the substrate).

When θ1=θ2, the meniscus position (the interface between the melt and the substrate) remains unchanged.

When θ1>θ2, the substrate 2 escapes while pressing the melt 6 when the surface of the substrate 2 goes out from the silicon melt 6 (the meniscus position (the interface between the melt and the substrate) progresses forwardly along the traveling direction of the substrate).

When θ1<θ2, the melt progresses in a direction separating from the substrate with reference to the substrate and the grown thin plate, and hence the melt cannot supply pressure to the substrate but readily remains on the surface of the substrate. Consequently, the melt remaining on the surface of the substrate is conceivably projected due to surface tension.

When θ1>θ2, on the other hand, the melt progresses in a direction regularly hitting (colliding against) the substrate, to regularly supply pressure to the substrate. Consequently, the melt hardly remains on the surface of the substrate, to conceivably reduce the number of projections.

(Seventh Embodiment)

Solar cells were prototyped with silicon polycrystalline thin plates 3 prepared according to the thin plate manufacturing apparatus and the thin plate manufacturing method in the aforementioned sixth embodiment through prototype processes (first to eighth processes) similar to those in the aforementioned fifth embodiment. FIG. 10 shows the numbers of projections as well as yields and conversion efficiencies of the solar cells prototyped at substrate inclinations [θ1°] of 1.4°, 5.7° and 10° in trajectory steps of substrates 2.

While it was possible to uniformly perform printing in formation of electrodes when the substrate inclination [θ1°] was 10° since the number of projections was zero, printed electrodes were partially bled or broken when [θ1] was 1.4° due to an influence by projections (formed by 20). The efficiency percentage (solar cell prototype yield) in the case of prototyping a solar cell is at a low level of 84% due to disconnection of the yield. In the case of the silicon polycrystalline thin plate 3 suppressing projections, on the other hand, it was possible to improve the yield to 92%. While a solar cell conversion efficiency at the time of prototyping a solar cell with a silicon polycrystalline thin plate 3 according to the background technique is at a low level of 12% due to an influence by bleeding of electrodes, it was possible to improve the efficiency to 13% in the case of the silicon polycrystalline thin plate 3 suppressing projections.

(Eighth Embodiment)

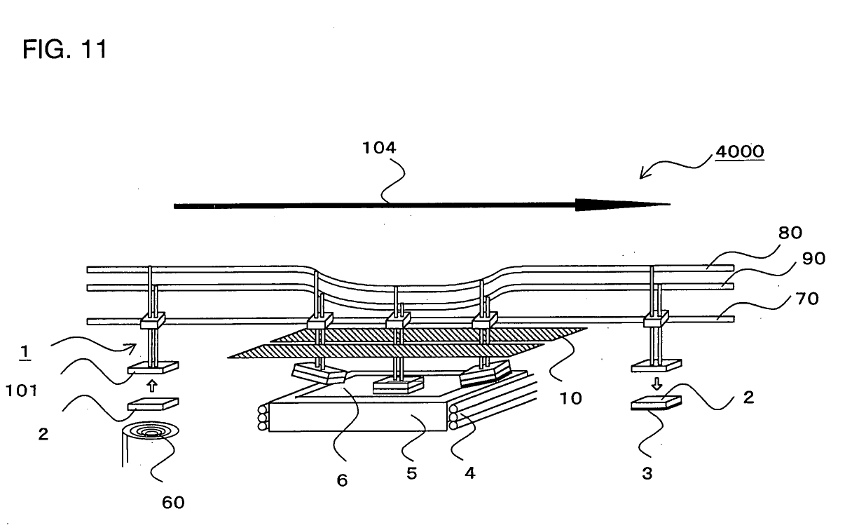

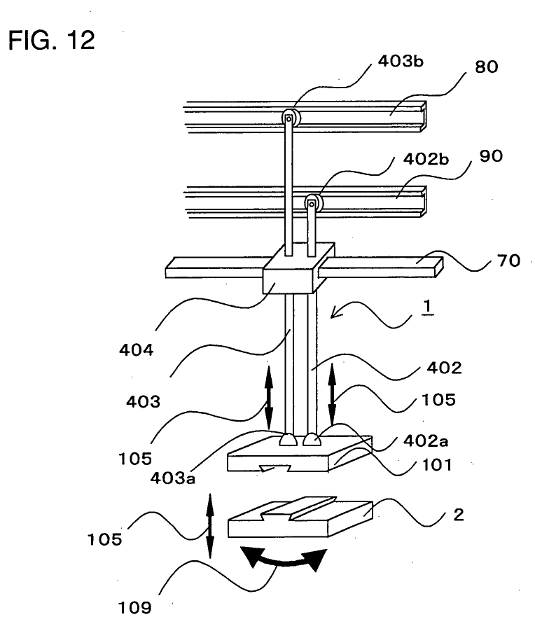

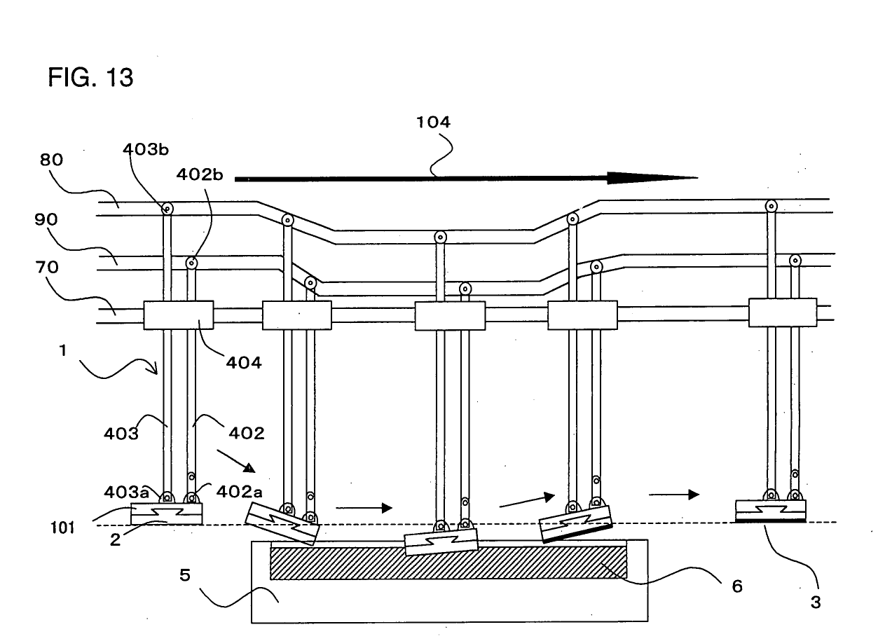

A thin plate manufacturing apparatus according to this embodiment is now described with reference to FIGS. 11 to 13. FIG. 11 is a schematic diagram showing the overall structure of a thin plate manufacturing apparatus 4000 in this embodiment, FIG. 12 is an enlarged view of a substrate transport mechanism 1 described later, and FIG. 13 illustrates the trajectory of the substrate transport mechanism 1.

(Overall Structure of Thin Plate Manufacturing Apparatus 4000)

The overall structure of the thin plate manufacturing apparatus 4000 according to this embodiment is now described with reference to FIGS. 11 and 12. The basic structure of this thin plate manufacturing apparatus 4000 is identical to that of the thin plate manufacturing apparatus 1000 described with reference to the aforementioned first embodiment, and a different point resides in the structure of the substrate transport mechanism 1. Therefore, identical or corresponding portions are denoted by the same reference numerals, and redundant description is not repeated.

Substrate temperature control means 60 is provided for controlling the surface temperature of a substrate 2 (cooling or heating to a prescribed temperature) before dipping the substrate 2 in a melt 6. This substrate temperature control means 60 is so provided that it is possible to optimize the surface temperature of the substrate when forming a thin plate on the surface of the substrate 2. A coiled hollow heat transfer member is employed as the substrate temperature control means 60 so that the surface temperature of the substrate 2 can be increased when the heat transfer member itself is heated while the surface temperature of the substrate 2 can be reduced by passing a cooling medium through the heat transfer member.

The substrate transport mechanism 1 in this embodiment includes a substrate fixing member 101 for fixing the substrate 2, horizontal movement position control means for controlling a horizontal movement position of the substrate fixing member 101 for controlling a horizontal movement position of the surface of the substrate 2 with respect to the level of the melt 6, vertical movement position control means for controlling a vertical movement position of the substrate fixing member 101 for controlling a vertical movement position of the surface of the substrate 2 with respect to the level of the melt 6 and substrate inclination means for controlling an inclination of the substrate fixing member 101 for inclining the surface of the substrate 2 with respect to the level of the melt 6.

The horizontal movement position control means has a horizontal guide rail 70 extending in a horizontal direction 104 and a horizontal moving unit 404 movably provided along this horizontal guide rail 70. This horizontal moving unit 404 stores a drive for moving the same on the horizontal guide rail 70.

The vertical movement position control means has a vertical guide shaft 403 supported to be slidable in a vertical direction 105 in the horizontal moving unit 404 so that the substrate fixing member 101 is coupled to its lower end and a vertical guide rail 80 provided along the horizontal guide rail 70 for guiding a movement position of the upper end of the vertical guide shaft 403. The lower end of the vertical guide shaft 403 is rotatably coupled to the substrate fixing member 101 by a pivotal part 403a, while the upper end of the vertical guide shaft 403 is provided with an upper end guide roller 403b guided by the vertical guide rail 80.

The substrate inclination means has an inclination guide shaft 402 supported to be vertically slidable in the horizontal moving unit 404 so that the substrate fixing member 101 is coupled to its lower end and an inclination guide rail 90 provided along the horizontal guide rail 70 for guiding the upper end of the inclination guide shaft 402. The lower end of the inclination guide shaft 402 is rotatably coupled to the substrate fixing member 101 by a pivotal part 402a, while the upper end of the inclination guide shaft 402 is provided with an upper end guide roller 402b guided by the inclination guide rail 90.

(Trajectory of Substrate Transport Mechanism 1)

The trajectory for dipping the substrate 2 into the melt 6 in the substrate transport mechanism 1 is described with reference to FIG. 13. The thin plate manufacturing apparatus 4000 consisting of the aforementioned structure can horizontally move the vertical guide shaft 403 and the inclination guide shaft 402 following the horizontal moving unit 404 by moving the horizontal moving unit 404 along the horizontal guide rail 70. The directions of movement of the upper end guide rollers 403b and 402a of the vertical guide shaft 403 and the inclination guide shaft 402 are guided by the vertical guide rail 80 and the inclination guide rail 90 respectively, whereby the positions of the vertical guide shaft 403 and the inclination guide shaft 402 can be decided in a driven manner.

As to positioning of the vertical guide shaft 403 and the inclination guide shaft 402, trajectories of the vertical guide rail 80 and the inclination guide rail 90 are selected in correspondence to the vertical position and the inclination of the substrate fixing member 101 to be selected. Consequently, it is possible to provide the optimum trajectory for the substrate fixing member 101 and the substrate 2, as shown in FIG. 13.

(Functions/Effects)

According to the thin plate manufacturing apparatus 4000 in this embodiment, as hereinabove described, the substrate transport mechanism 1 can employ a structure of providing only the horizontal moving unit 404 forming the horizontal movement position control means with the drive without providing the respective ones of the horizontal movement position control means, the vertical movement position control means and the substrate inclination means with drives, whereby it is possible to simplify the structures of the substrate transport mechanisms 1 shown in the aforementioned first and second embodiments.

(Ninth Embodiment)

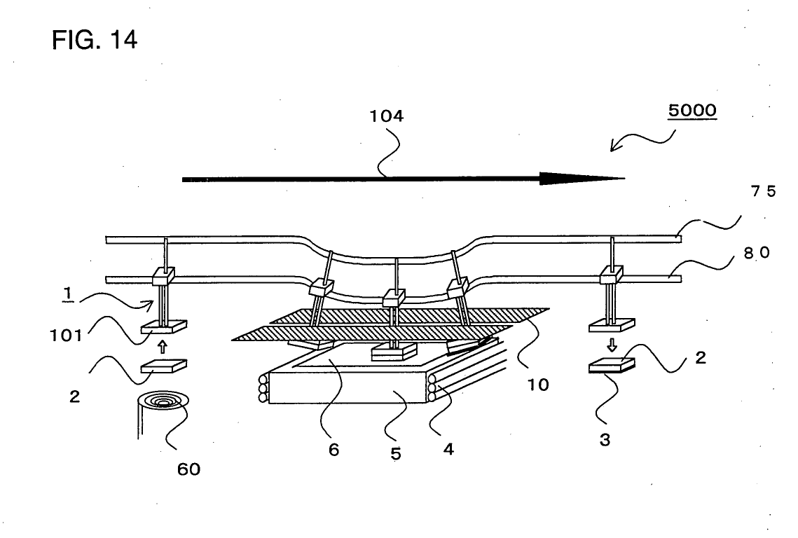

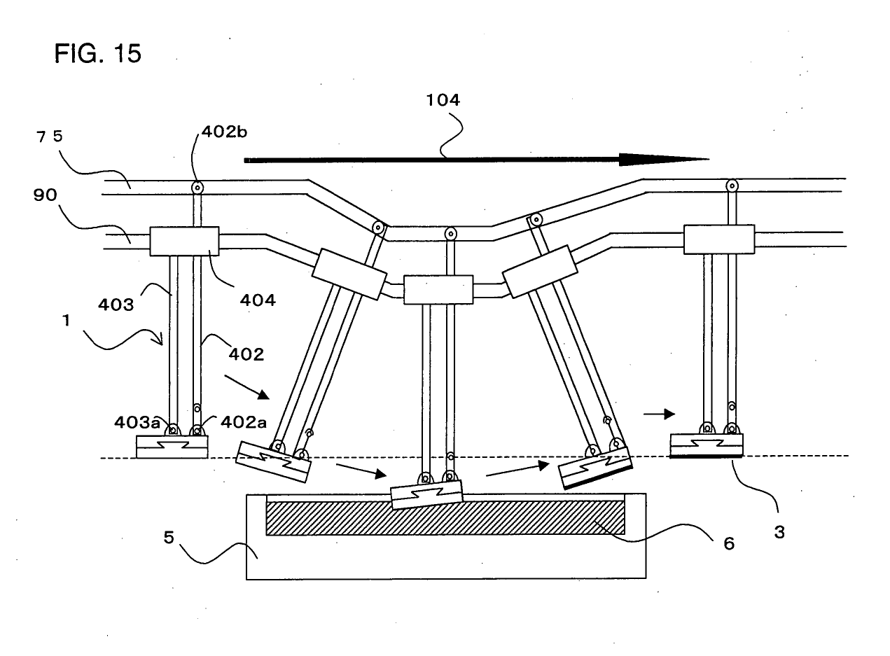

A thin plate manufacturing apparatus according to this embodiment is now described with reference to FIGS. 14 and 15. FIG. 14 is a schematic diagram showing the overall structure of a thin plate manufacturing apparatus 5000 according to this embodiment, and FIG. 15 illustrates the trajectory of a substrate transport mechanism 1.

(Overall Structure of Thin Plate Manufacturing Apparatus 5000)

The overall structure of the thin plate manufacturing apparatus 5000 according to this embodiment is described with reference to FIGS. 14 and 15. The basic structure of this thin plate manufacturing apparatus 5000 is identical to that of the thin plate manufacturing apparatus 4000 described with reference to the aforementioned eighth embodiment, and different points reside in that a horizontal/vertical guide rail 75 constituting a horizontal guide rail and a vertical guide rail in a shared manner is employed and that the upper end of a vertical guide shaft 403 is coupled to a horizontal moving unit 404. Therefore, portions identical or corresponding to those of the thin plate manufacturing apparatus 4000 are denoted by the same reference numerals, and redundant description is not repeated.

(Trajectory of Substrate Transport Mechanism 1)

Referring to FIG. 15, it is possible to horizontally move the vertical guide shaft 403 and the inclination guide shaft 402 following the horizontal moving unit 404 by moving the horizontal moving unit 404 along the horizontal/vertical guide rail 75 also in the thin plate manufacturing apparatus 5000 according to this embodiment, similarly to the trajectory of the substrate 2 in the substrate transport mechanism 1 in the eighth embodiment. The direction of movement of an upper end guide roller 402b of the inclination guide shaft 402 is guided by an inclination guide rail 90, whereby the position of the inclination guide shaft 402 can be decided in a driven manner.

As to positioning of the vertical guide shaft 403 and the inclination guide shaft 402, fixed states to the horizontal moving unit 404 and the trajectory of the inclination guide rail 90 are selected in correspondence to the vertical position and the inclination of a substrate fixing member 101 to be selected. Consequently, it is possible to provide the optimum trajectory for the substrate fixing member 101 and a substrate 2, as shown in FIG. 15.

(Functions/Effects)

According to the thin plate manufacturing apparatus 5000 in this embodiment, as hereinabove described, the substrate transport mechanism 1 can employ a structure of providing only the horizontal moving unit 404 forming horizontal movement position control means with a drive without providing the respective ones of horizontal movement position control means, vertical movement position control means and substrate inclination means with drives, whereby it is possible to simplify the structures of the substrate transport mechanisms 1 shown in the aforementioned first and second embodiments.

(Tenth Embodiment)

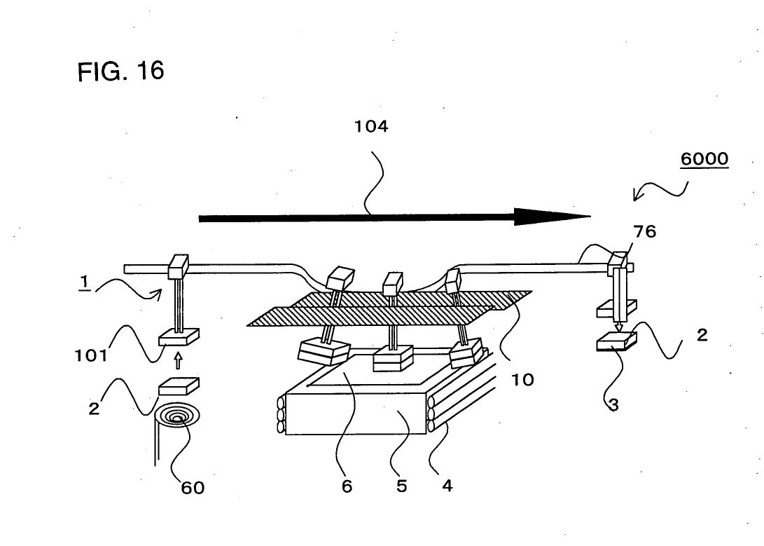

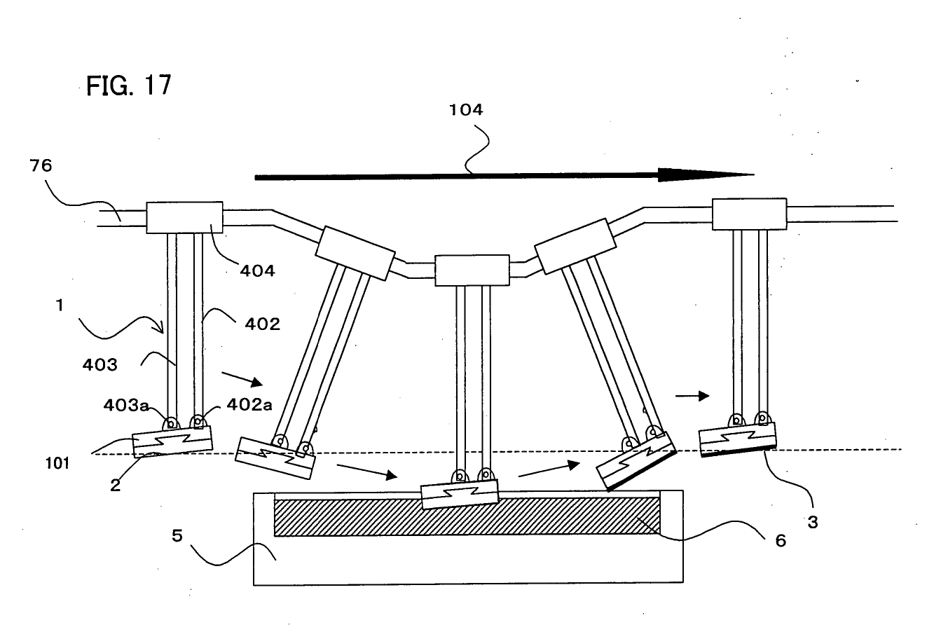

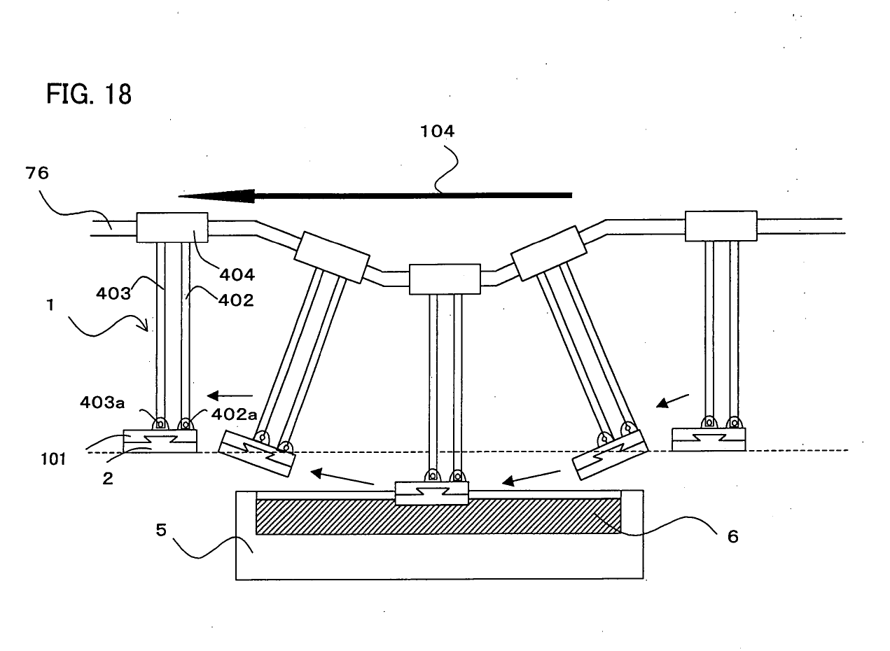

A thin plate manufacturing apparatus according to this embodiment is now described with reference to FIGS. 16 to 18. FIG. 16 is a schematic diagram showing the overall structure of a thin plate manufacturing apparatus 6000 according to this embodiment, FIG. 17 illustrates a supply trajectory of a substrate transport mechanism 1, and FIG. 18 illustrates a return trajectory of the substrate transport mechanism 1.

(Overall Structure of Thin Plate Manufacturing Apparatus 6000)

The overall structure of the thin plate manufacturing apparatus 6000 according to this embodiment is described with reference to FIGS. 16 and 17. The basic structure of this thin plate manufacturing apparatus 6000 is identical to that of the thin plate manufacturing apparatus 4000 described with reference to the aforementioned eighth embodiment, and different points reside in that a horizontal/vertical/inclination guide rail 76 constituting a horizontal guide rail, a vertical guide rail and an inclination guide rail in a shared manner is employed and that the upper ends of a vertical guide shaft 403 and an inclination guide shaft 402 are coupled to a horizontal moving unit 404. Therefore, portions identical or corresponding to those of the thin plate manufacturing apparatus 4000 are denoted by the same reference numerals, and redundant description is not repeated.

(Trajectory of Substrate Transport Mechanism 1)

Referring to FIG. 17, it is possible to horizontally move the vertical guide shaft 403 and the inclination guide shaft 402 following the horizontal moving unit 404 by moving the horizontal moving unit 404 along the horizontal/vertical/inclination guide rail 76 also in the thin plate manufacturing apparatus 6000 according to this embodiment, similarly to the trajectory of the substrate 2 in the substrate transport mechanism 1 in the eighth embodiment.

As to positioning of the vertical guide shaft 403 and the inclination guide shaft 402, fixed states to the horizontal moving unit 404 are selected in correspondence to the vertical position and the inclination of a substrate fixing member 101 to be selected. Consequently, it is possible to provide the optimum supply trajectory for the substrate fixing member 101 and a substrate 2, as shown in FIG. 17. It is also possible to supply the optimum return trajectory for the substrate fixing member 101 and the substrate 2, as shown in FIG. 18.

(Functions/Effects)

According to the thin plate manufacturing apparatus 6000 in this embodiment, as hereinabove described, the substrate transport mechanism 1 can employ a structure of providing only the horizontal moving unit 404 forming horizontal movement position control means with a drive without providing the respective ones of horizontal movement position control means, vertical movement position control means and substrate inclination means with drives, whereby it is possible to simplify the structures of the substrate transport mechanisms 1 shown in the aforementioned first and second embodiments.

(Eleventh Embodiment)

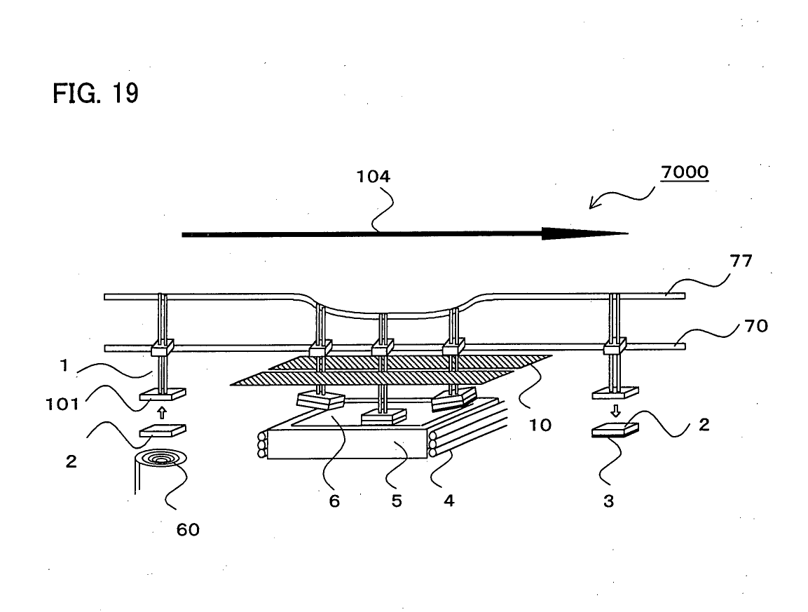

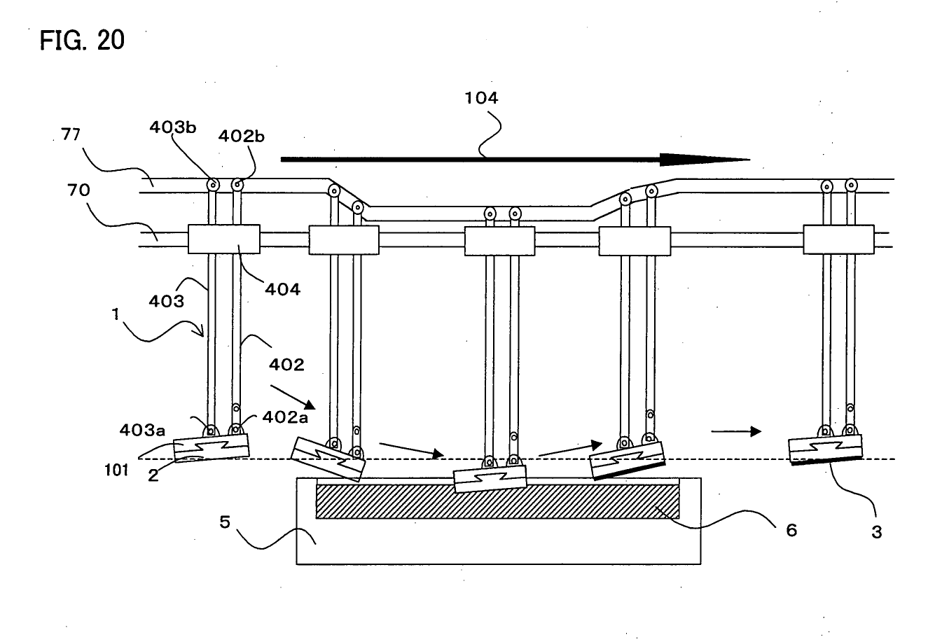

A thin plate manufacturing apparatus according to this embodiment is now described with reference to FIGS. 19 and 20. FIG. 19 is a schematic diagram showing the overall structure of a thin plate manufacturing apparatus 7000 according to this embodiment, and FIG. 20 illustrates the trajectory of a substrate transport mechanism 1.

(Overall Structure of Thin Plate Manufacturing Apparatus 7000)

The overall structure of the thin plate manufacturing apparatus 7000 according to this embodiment is described with reference to FIGS. 19 and 20. The basic structure of this thin plate manufacturing apparatus 7000 is identical to that of the thin plate manufacturing apparatus 4000 described with reference to the aforementioned eighth embodiment, and a different point resides in that a vertical/inclination guide rail 77 constituting a vertical guide rail and an inclination guide rail in a shared manner is employed. Therefore, portions identical or corresponding to those of the thin plate manufacturing apparatus 4000 are denoted by the same reference numerals, and redundant description is not repeated.

(Trajectory of Substrate Transport Mechanism 1)

Referring to FIG. 20, it is possible to horizontally move a vertical guide shaft 403 and an inclination guide shaft 402 following a horizontal moving unit 404 by moving the horizontal moving unit 404 along a horizontal guide rail 70 also in the thin plate manufacturing apparatus 7000 according to this embodiment, similarly to the trajectory of the substrate 2 in the substrate transport mechanism 1 in the eighth embodiment. The directions of movement of upper end guide rollers 403b and 402a of the vertical guide shaft 403 and the inclination guide shaft 402 are guided by the vertical/inclination guide rail 77, whereby the positions of the vertical guide shaft 403 and the inclination guide shaft 402 can be decided in a driven manner.

As to positioning of the vertical guide shaft 403 and the inclination guide shaft 402, the trajectory of the vertical/inclination guide rail 77 is selected in correspondence to the vertical position and the inclination of a substrate fixing member 101 to be selected. Consequently, it is possible to provide the optimum trajectory for the substrate fixing member 101 and a substrate 2, as shown in FIG. 20.

(Functions/Effects)

According to the thin plate manufacturing apparatus 5000 in this embodiment, as hereinabove described, the substrate transport mechanism 1 can employ a structure of providing only the horizontal moving unit 404 forming horizontal movement position control means with a drive without providing the respective ones of horizontal movement position control means, vertical movement position control means and substrate inclination means with drives, whereby it is possible to simplify the structures of the substrate transport mechanisms 1 shown in the aforementioned first and second embodiments.

While both ends of the linear rails constituting the horizontal moving shafts 8, the horizontal guide rails 70, the vertical guide rails 80, the inclination guide rails 90, the horizontal/vertical guide rail 75, the horizontal/vertical/inclination guide rail 76 and the vertical/inclination guide rail 77 are omitted in the aforementioned respective embodiments, it is also possible to employ a structure of forming a caterpillar in each rail thereby circulating the substrate transport mechanism 1, and it is also possible to employ a structure of attaching the substrate transport mechanism 1 from an end of each rail and separating the substrate transport mechanism 1 from the other end.

While each of the aforementioned embodiments has been described with reference to the case of preparing the silicon polycrystalline thin plate 3, it is also possible to attain similar functions/effects also in a thin plate corresponding to a used melt material when employing a semiconductor material such as germanium, gallium, arsenic, indium, phosphorus, boron, antimony, zinc or tin or a metallic material such as aluminum, nickel or iron for the melt.

The embodiments disclosed this time must be considered illustrative in all points and not restrictive. The scope of the present invention is shown not by the above description but by the scope of claim for patent, and it is intended that all changes within the meaning and the range equivalent to the scope of claim for patent are included.

(Effects of the Invention)

According to the thin plate manufacturing apparatus and the thin plate manufacturing method in the present invention, the correlation between the substrate (and the thin plate grown on the substrate) and the melt is optimized by controlling the trajectory of the substrate, so that it is possible to attain improvement of the quality and the shape of the thin plate (prevention of a dripping and formation of projections) and improvement of mass productivity of the thin plate.

According to another aspect of the thin plate manufacturing apparatus in the present invention, the substrate transport mechanism can employ the structure of providing only the horizontal movement position control means with the drive without providing the respective ones of the horizontal movement position control means, the vertical movement position control means and the substrate inclination means with drives, whereby it is possible to simplify the structure of the substrate transport mechanism.

1. A thin plate manufacturing apparatus for dipping a substrate held by a substrate transport mechanism into a melt thereby forming a thin plate on the surface of said substrate, wherein
said substrate transport mechanism includes:
first substrate transport means for transporting said substrate in a direction for dipping and taking out said substrate into and from said melt, and
second substrate transport means enabling transport of said substrate in a second direction different from said first direction.

2. The thin plate manufacturing apparatus according to claim 1, capable of independently controlling said first substrate transport means and said second substrate transport means respectively.

3. The thin plate manufacturing apparatus according to claim 1, wherein said substrate transport mechanism further includes substrate inclination means for inclining the surface of said substrate with respect to the level of said melt.

4. The thin plate manufacturing apparatus according to claim 1, wherein said substrate inclination means is independently controllable with respect to said first substrate transport means and said second substrate transport means.

5. The thin plate manufacturing apparatus according to claim 1, wherein said substrate transport mechanism further includes substrate attaching/detaching means for rendering said substrate attachable/detachable to/from said substrate transport mechanism.

6. The thin plate manufacturing apparatus according to claim 5, wherein said substrate attaching/detaching means is independently controllable with respect to said first substrate transport means, said second substrate transport means and said substrate inclination means.

7. The thin plate manufacturing apparatus according to claim 5, wherein said substrate attaching/detaching means includes steps of:
attaching said substrate to said substrate transport mechanism before dipping said substrate, and
detaching said substrate having the thin plate grown on its surface from said substrate transport mechanism after dipping said substrate.

8. The thin plate manufacturing apparatus according to claim 5, comprising a step of detaching the thin plate grown on the surface of said substrate from said substrate while keeping said substrate attached to said substrate transport mechanism after dipping said substrate.

9. The thin plate manufacturing apparatus according to claim 1, comprising melt holding means holding said melt, and
further comprising thermal shield means between said melt holding means and said substrate transport mechanisms.

10. The thin plate manufacturing apparatus according to claim 1, wherein said substrate transport mechanism includes:
dip control means dipping said substrate into said melt of a material containing at least either a metallic material or a semiconductor material, and
thin plate growth control means taking out dipped said substrate from said melt thereby growing the thin plate of said material on the surface of said substrate.

11. The thin plate manufacturing apparatus according to claim 8, wherein said dip control means independently controls said first substrate transport means and said second substrate transport means respectively after said substrate is dipped into said melt and before said substrate is taken out from said melt for growing the thin plate on the surface of said substrates.

12. The thin plate manufacturing apparatus according to claim 9, wherein said dip control means controls said substrate inclination means independently of said first substrate transport means and said second substrate transport means after said substrate is dipped into said melt and before said substrate is taken out from said melt.

13. The thin plate manufacturing apparatus according to claim 1, wherein said melt is a material including silicon.

14. A thin plate manufacturing method holding a substrate with a substrate transport mechanism and dipping said substrate into a melt thereby forming a thin plate on the surface of said substrate, comprising a step of:
independently controlling first substrate transport means for transporting said substrate in a direction for dipping and taking out said substrate into and from said melt and second substrate transport means enabling transport of said substrate in a second direction different from said first direction
after said substrate is dipped into said melt and before said substrate is taken out from said melt.

15. The thin plate manufacturing method according to claim 14, wherein said step includes a step of:
taking out said substrate from said melt while inclining said substrate and pressing the surface of said melt with said substrates.

16. The thin plate manufacturing method according to claim 14, comprising steps of:
attaching said substrate to said substrate transport mechanism before dipping said substrates, and
detaching said substrates having the thin plate grown on its surface from said substrate transport mechanism after dipping said substrates.

17. The thin plate manufacturing method according to claim 14, comprising a step of detaching the thin plate grown on the surface of said substrate from said substrate while keeping said substrate attached to said substrate transport mechanism after dipping said substrates.

18. The thin plate manufacturing method according to claim 14, wherein said melt is a material including silicon.

19. A solar cell manufactured with a thin plate prepared with a thin plate manufacturing apparatus for dipping a substrate held by a substrate transport mechanism into a melt thereby forming a thin plate on the surface of said substrate, wherein
said substrate transport mechanism includes first substrate transport means for transporting said substrate in a direction for dipping and taking out said substrate into and from said melt and second substrate transport means enabling transport of said substrate in a second direction different from said first direction.

20. A solar cell manufactured with a thin plate prepared by a thin plate manufacturing method for holding a substrate with a substrate transport mechanism and dipping said substrate into a melt thereby forming a thin plate on the surface of said substrate, comprising a step of:
independently controlling first substrate transport means for transporting said substrate in a direction for dipping and taking out said substrate Pinto and from said melt and second substrate transport means enabling transport of said substrate in a second direction different from said first direction after said substrate is dipped into said melt and before said substrate is taken out from said melt.

21. A thin plate manufacturing apparatus for dipping a substrate held by a substrate transport mechanism into a melt thereby forming a thin plate on the surface of said substrate, wherein
said substrate transport mechanism includes:
substrate fixing means for fixing said substrate,
horizontal movement position control means for controlling a horizontal movement position of said substrate fixing means for controlling a horizontal movement position of the surface of said substrate with respect to the level of said melt
vertical movement position control means for controlling a vertical movement position of said substrate fixing means for controlling a vertical movement position of the surface of said substrate with respect to the level of said melt, and
substrate inclination means for controlling an inclination of said substrate fixing means for inclining the surface of said substrate with respect to the level of said melt,
said horizontal movement position control means has:
a horizontally extending horizontal guide rail, and
a horizontal moving unit movably provided along said horizontal guide rail,
said vertical movement position control means has:
a vertical guide shaft vertically slidably supported in said horizontal moving unit so that said substrate fixing means is coupled to its lower end, and
a vertical guide rail provided along said horizontal guide rail for guiding a movement position of the upper end of said vertical guide shaft, and
said substrate inclination means has:
an inclination guide shaft vertically movably supported in said horizontal moving unit so that said substrate fixing means is coupled to its lower end, and
an inclination guide rail provided along said horizontal guide rail for guiding the upper end of said inclination guide shaft.

22. A thin plate manufacturing apparatus for dipping a substrate held by a substrate transport mechanism into a melt thereby forming a thin plate on the surface of said substrate, wherein
said substrate transport mechanism includes:
substrate fixing means for fixing said substrate,
horizontal movement position control means for controlling a horizontal movement position of said substrate fixing means for controlling a horizontal movement position of the surface of said substrate with respect to the level of said melt,
vertical movement position control means for controlling a vertical movement position of said substrate fixing means for controlling a vertical movement position of the surface of said substrate with respect to the level of said melt, and
substrate inclination means for controlling an inclination of said substrate fixing means for inclining the surface of said substrate with respect to the level of said melt,
said horizontal movement position control means has:
a horizontally extending horizontal/vertical guide rail, and
a horizontal moving unit movably provided along said horizontal/vertical guide rail,
said vertical movement position control means has:
a vertical guide shaft having an upper end coupled to said horizontal moving unit and a lower end coupled with said substrate fixing means, and
said substrate inclination means has:
an inclination guide shaft vertically slidably supported so that said substrate fixing means is coupled to its lower end, and
an inclination guide rail provided along said horizontal/vertical guide rail for guiding the upper end of said inclination guide shaft.

23. A thin plate manufacturing apparatus for dipping a substrate held by a substrate transport mechanism into a melt thereby forming a thin plate on the surface of said substrate, wherein
said substrate transport mechanism includes:
substrate fixing means for fixing said substrates,
horizontal movement position control means for controlling a horizontal movement position of said substrate fixing means for controlling a horizontal movement position of the surface of said substrate with respect to the level of said melt,
vertical movement position control means for controlling a vertical movement position of said substrate fixing means for controlling a vertical movement position of the surface of said substrate with respect to the level of said melt, and
substrate inclination means for controlling an inclination of said substrate fixing means for inclining the surface of said substrate with respect to the level of said melt,
said horizontal movement position control means has:
a horizontally extending horizontal/vertical/inclination guide rail, and a horizontal moving unit movably provided along said horizontal/vertical/inclination guide rail,
said vertical movement position control means has:
a vertical guide shaft having an upper end coupled to said horizontal moving unit and a lower end coupled with said substrate fixing means, and
said substrate inclination means has:
an inclination guide shaft having an upper end coupled to said horizontal moving unit and a lower end coupled with said substrate fixing means.

24. A thin plate manufacturing apparatus for dipping a substrate held by a substrate transport mechanism into a melt thereby forming a thin plate on the surface of said substrate, wherein
said substrate transport mechanism includes:
substrate fixing means for fixing said substrates,
horizontal movement position control means for controlling a horizontal movement position of said substrate fixing means for controlling a horizontal movement position of the surface of said substrate with respect to the level of said melt,
vertical movement position control means for controlling a vertical movement position of said substrate fixing means for controlling a vertical movement position of the surface of said substrate with respect to the level of said melt, and
substrate inclination means for controlling an inclination of said substrate fixing means for inclining the surface of said substrate with respect to the level of said melt,
said horizontal movement position control means has:
a horizontally extending horizontal guide rail, and
a horizontal moving unit movably provided along said horizontal guide rail
said vertical movement position control means has:
a vertical guide shaft vertically slidably supported in said horizontal moving unit so that said substrate fixing means is coupled to its lower end, and
a vertical/inclination guide rail provided along said horizontal guide rail for guiding a movement position of the upper end of said vertical guide shaft, and
said substrate inclination means has:
an inclination guide shaft vertically slidably supported in said horizontal moving unit so that said substrate fixing means is coupled to its lower end and a movement position of its upper end is guided by said vertical/inclination guide rail.

25. The thin plate manufacturing apparatus according to claim 1, further comprising substrate temperature control means (60) for controlling the temperature on the surface of said substrate before dipping said substrate into said melt.
